(19) United States
(12) Patent Application Publication
(10) Pub. No.: US 2024/0147731 A1
(43) Pub. Date: May 2, 2024

(54) SEMICONDUCTOR DEVICES AND METHODS OF FORMATION

(71) Applicant: Taiwan Semiconductor Manufacturing Company, Ltd., Hsinchu (TW)

(72) Inventors: Yi-Hsuan CHEN, Taoyuan City (TW); Kuen-Yi CHEN, Hsinchu City (TW); Yi Ching ONG, Hsinchu (TW); Kuo-Ching HUANG, Hsinchu City (TW)

(21) Appl. No.: 18/303,131

(22) Filed: Apr. 19, 2023

Related U.S. Application Data
(60) Provisional application No. 63/381,674, filed on Oct. 31, 2022.

(51) Int. Cl. H10B 51/30; H01L 29/51; H01L 29/66; H01L 29/78

(52) U.S. Cl. CPC H10B 51/30; H01L 29/516; H01L 29/6684; H01L 29/78391

(57) ABSTRACT

An interfacial layer is formed in a manner that enables a ferroelectric layer to be formed such that formation of ferroelectric crystalline phases (e.g., orthorhombic crystalline phases) in the ferroelectric layer is increased and formation of non-ferroelectric crystalline phases (e.g., monoclinic phases, tetragonal phases) in the ferroelectric layer is reduced. To achieve this, the grain size and/or other properties of the interfacial layer may be controlled during formation of the interfacial layer such that the grain size and/or other properties of the interfacial layer facilitate formation of a larger grain size in the ferroelectric layer. At larger grain sizes in the ferroelectric layer, the concentration of the ferroelectric crystalline phases in the crystal structure of the ferroelectric layer may be increased relative to if the ferroelectric layer were formed to a smaller grain size.

### CROSS-REFERENCE TO RELATED APPLICATION

This Patent application claims priority to U.S. Provisional Patent Application No. 63/381,674, filed on Oct. 31, 2022, and entitled “SEMICONDUCTOR DEVICES AND METHODS OF FORMATION.” The disclosure of the prior Application is considered part of and is incorporated by reference into this Patent Application.

### BACKGROUND

A ferroelectric random access memory (FeRAM) cell is a type of random-access memory cell that utilizes a ferroelectric field effect transistor (FeFET) that includes a ferroelectric (FE) layer to selectively store information based on polarization of the ferroelectric layer. For example, a first voltage may be applied to a gate structure of the FeFET to cause the ferroelectric layer to be polarized in a first polarization configuration corresponding to a programmed state of the FeRAM cell, and a second voltage may be applied to the gate structure to cause the ferroelectric layer to be polarized in a second polarization configuration corresponding to an erased state of the FeRAM cell.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example environment in which systems and/or methods described herein may be implemented.

FIGS. 2A-2C are diagrams of example implementations of ferroelectric tunnel junction (FTJ) structures described herein.

FIGS. 3A and 3B are diagrams of example implementations of ferroelectric random access memory (FeRAM) structures described herein.

FIGS. 4A and 4B are diagrams of example implementations of current distributions of FTJ structures described herein.

FIGS. 5A-5F are diagrams of an example implementation of forming an FTJ structure described herein.

FIGS. 6A-6F are diagrams of an example implementation of forming an FTJ structure described herein.

FIG. 7 is a diagram of an example implementation of phase composition of a ferroelectric layer of an FTJ structure described herein.

FIG. 8 is a diagram of a portion of an example device described herein.

FIG. 9 is a diagram of example components of a device described herein.

FIG. 10 is a flowchart of an example process associated with forming a semiconductor device described herein.

FIG. 11 is a flowchart of an example process associated with forming a semiconductor device described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A ferroelectric layer may be included in a ferroelectric tunnel junction (FTJ) structure in which the ferroelectric layer is included between two or more electrodes. An FTJ structure may be used to implement a ferroelectric random access memory (FeRAM) cell, a ferroelectric field effect transistor (FeFET), and/another type of semiconductor device that operates based on ferroelectric-based switching principles.

Ferroelectric properties of a ferroelectric layer may include coercive field (E_{c}), remnant polarization (Pᵣ) area density, and/or polarization-electric field (P-E) hysteresis loop squareness, among other examples. The ferroelectric properties of a ferroelectric layer may depend upon a crystal structure of the ferroelectric layer. For example, ferroelectric properties such as remnant polarization area density may increase as the presence of ferroelectric crystalline phases (e.g., orthorhombic crystalline phases) in the crystal structure of the ferroelectric layer increases. Conversely, the remnant polarization area density of the ferroelectric layer may decrease as the presence of non-ferroelectric crystalline phases (e.g., monoclinic phases, tetragonal phases) in the ferroelectric layer is increased.

Remnant polarization is the amount of polarization that remains in the ferroelectric layer after an external polarization force (e.g., an electric field) is removed. Thus, reduced remnant polarization area density may result in reduced ability to store and retain data in an FeRAM cell that includes the ferroelectric layer due to a reduced memory window size of the FeRAM cell. In particular, remnant polarization area density may reduce the difference in the amount of remaining polarization in the ferroelectric layer between a programmed state and an erased state of the FeRAM cell. This difference is referred to as the memory window size, and a reduced memory window size can lead to data corruption in the FeRAM cell, read errors in the FeRAM cell, and/or another type of performance degradation. Moreover, reduced remnant polarization area density may result in reduced cell-to-cell uniformity of FeRAM cells, and therefore reduced yield and increased performance variation of FeRAM cells.

In some implementations described herein, an interfacial layer is formed in a manner that enables the formation of a ferroelectric layer on the interfacial layer to be highly controlled. In particular, the interfacial layer is formed in a manner that enables the ferroelectric layer to be formed to increase the formation of ferroelectric crystalline phases (e.g., orthorhombic crystalline phases) in the ferroelectric layer, and to reduce the formation of non-ferroelectric crystalline phases (e.g., monoclinic phases, tetragonal phases) in the ferroelectric layer. To achieve this, the grain size and/or other properties of the interfacial layer may be controlled during formation of the interfacial layer such that the grain size and/or other properties of the interfacial layer facilitate formation of a larger grain size in the ferroelectric layer. At larger grain sizes in the ferroelectric layer, the concentration of ferroelectric crystalline phases (e.g., orthorhombic crystalline phases) in the crystal structure of the ferroelectric layer may be increased relative to smaller grain sizes in the ferroelectric layer.

Increasing the presence of ferroelectric crystalline phases in the ferroelectric layer may increase one or more ferroelectric properties of the ferroelectric layer, such as increased coercive field (E_{c}), increased remnant polarization (Pᵣ) area density, and/or increased polarization-electric field (P-E) hysteresis loop squareness, among other examples. Increasing the remnant polarization (Pᵣ) area density may increase a memory window size of an FeRAM cell that includes the interfacial layer and the ferroelectric layer that is formed on the interfacial layer described herein. The increased memory window size may reduce the likelihood of data corruption in the FeRAM cell, may increase data retention performance in the FeRAM cell, and/or may reduce the likelihood and/or rate of read errors in the FeRAM cell, among other examples. Moreover, the increased remnant polarization area density may result in increased cell-to-cell uniformity of FeRAM cells, and therefore increased yield and decreased performance variation of FeRAM cells.

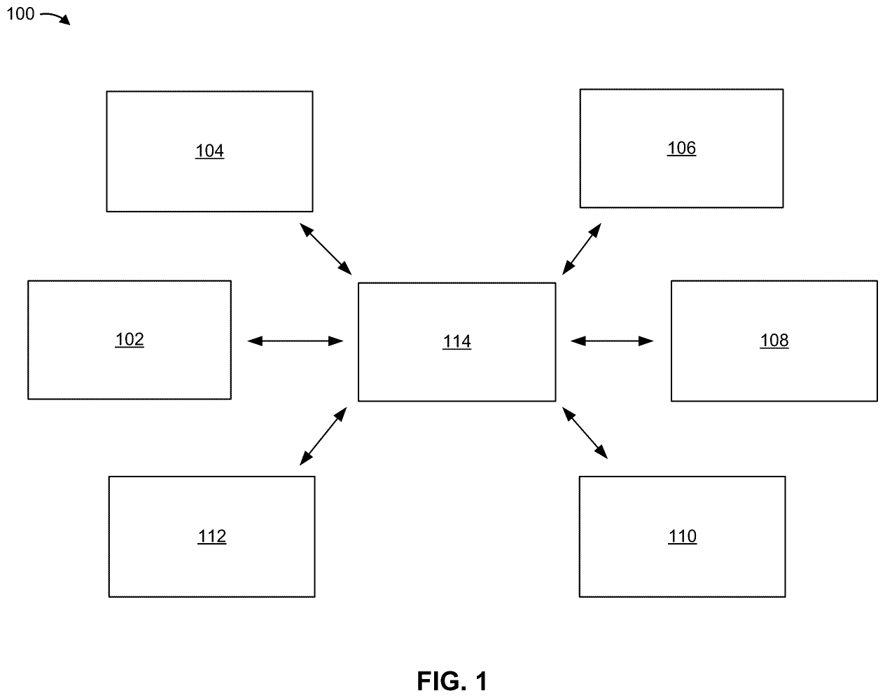

FIG. 1 is a diagram of an example environment 100 in which systems and/or methods described herein may be implemented. As shown in FIG. 1, the example environment 100 may include a plurality of semiconductor processing tools 102-112 and a wafer/die transport tool 114. The plurality of semiconductor processing tools 102-112 may include a deposition tool 102, an exposure tool 104, a developer tool 106, an etch tool 108, a planarization tool 110, a plating tool 112, and/or another type of semiconductor processing tool. The tools included in example environment 100 may be included in a semiconductor clean room, a semiconductor foundry, a semiconductor processing facility, and/or manufacturing facility, among other examples.

The deposition tool 102 is a semiconductor processing tool that includes a semiconductor processing chamber and one or more devices capable of depositing various types of materials onto a substrate. In some implementations, the deposition tool 102 includes a spin coating tool that is capable of depositing a photoresist layer on a substrate such as a wafer. In some implementations, the deposition tool 102 includes a chemical vapor deposition (CVD) tool such as a plasma-enhanced CVD (PECVD) tool, a high-density plasma CVD (HDP-CVD) tool, a sub-atmospheric CVD (SACVD) tool, a low-pressure CVD (LPCVD) tool, an atomic layer deposition (ALD) tool, a plasma-enhanced atomic layer deposition (PEALD) tool, or another type of CVD tool. In some implementations, the deposition tool 102 includes a physical vapor deposition (PVD) tool, such as a sputtering tool or another type of PVD tool. In some implementations, the deposition tool 102 includes an epitaxial tool that is configured to form layers and/or regions of a device by epitaxial growth. In some implementations, the example environment 100 includes a plurality of types of deposition tools 102.

The exposure tool 104 is a semiconductor processing tool that is capable of exposing a photoresist layer to a radiation source, such as an ultraviolet (UV) light source (e.g., a deep UV light source, an extreme UV (EUV) light source, and/or the like), an x-ray source, an electron beam (e-beam) source, and/or the like. The exposure tool 104 may expose a photoresist layer to the radiation source to transfer a pattern from a photomask to the photoresist layer. The pattern may include one or more semiconductor device layer patterns for forming one or more semiconductor devices, may include a pattern for forming one or more structures of a semiconductor device, may include a pattern for etching various portions of a semiconductor device, and/or the like. In some implementations, the exposure tool 104 includes a scanner, a stepper, or a similar type of exposure tool.

The developer tool 106 is a semiconductor processing tool that is capable of developing a photoresist layer that has been exposed to a radiation source to develop a pattern transferred to the photoresist layer from the exposure tool 104. In some implementations, the developer tool 106 develops a pattern by removing unexposed portions of a photoresist layer. In some implementations, the developer tool 106 develops a pattern by removing exposed portions of a photoresist layer. In some implementations, the developer tool 106 develops a pattern by dissolving exposed or unexposed portions of a photoresist layer through the use of a chemical developer.

The etch tool 108 is a semiconductor processing tool that is capable of etching various types of materials of a substrate, wafer, or semiconductor device. For example, the etch tool 108 may include a wet etch tool, a dry etch tool, and/or the like. In some implementations, the etch tool 108 includes a chamber that is filled with an etchant, and the substrate is placed in the chamber for a particular time period to remove particular amounts of one or more portions of the substrate. In some implementations, the etch tool 108 may etch one or more portions of the substrate using a plasma etch or a plasma-assisted etch, which may involve using an ionized gas to isotropically or directionally etch the one or more portions.

The planarization tool 110 is a semiconductor processing tool that is capable of polishing or planarizing various layers of a wafer or semiconductor device. For example, a planarization tool 110 may include a chemical mechanical planarization (CMP) tool and/or another type of planarization tool that polishes or planarizes a layer or surface of deposited or plated material. The planarization tool 110 may polish or planarize a surface of a semiconductor device with a combination of chemical and mechanical forces (e.g., chemical etching and free abrasive polishing). The planarization tool 110 may utilize an abrasive and corrosive chemical slurry in conjunction with a polishing pad and retaining ring (e.g., typically of a greater diameter than the semiconductor device). The polishing pad and the semiconductor device may be pressed together by a dynamic polishing head and held in place by the retaining ring. The dynamic polishing head may rotate with different axes of rotation to remove material and even out any irregular topography of the semiconductor device, making the semiconductor device flat or planar.

The plating tool 112 is a semiconductor processing tool that is capable of plating a substrate (e.g., a wafer, a semiconductor device, and/or the like) or a portion thereof with one or more metals. For example, the plating tool 112 may include a copper electroplating device, an aluminum electroplating device, a nickel electroplating device, a tin electroplating device, a compound material or alloy (e.g., tin-silver, tin-lead, and/or the like) electroplating device, and/or an electroplating device for one or more other types of conductive materials, metals, and/or similar types of materials.

Wafer/die transport tool 114 includes a mobile robot, a robot arm, a tram or rail car, an overhead hoist transport (OHT) system, an automated materially handling system (AMHS), and/or another type of device that is configured to transport substrates and/or semiconductor devices between semiconductor processing tools 102-112, that is configured to transport substrates and/or semiconductor devices between processing chambers of the same semiconductor processing tool, and/or that is configured to transport substrates and/or semiconductor devices to and from other locations such as a wafer rack, a storage room, and/or the like. In some implementations, wafer/die transport tool 114 may be a programmed device that is configured to travel a particular path and/or may operate semi-autonomously or autonomously. In some implementations, the example environment 100 includes a plurality of wafer/die transport tools 114.

For example, the wafer/die transport tool 114 may be included in a cluster tool or another type of tool that includes a plurality of processing chambers, and may be configured to transport substrates and/or semiconductor devices between the plurality of processing chambers, to transport substrates and/or semiconductor devices between a processing chamber and a buffer area, to transport substrates and/or semiconductor devices between a processing chamber and an interface tool such as an equipment front end module (EFEM), and/or to transport substrates and/or semiconductor devices between a processing chamber and a transport carrier (e.g., a front opening unified pod (FOUP)), among other examples. In some implementations, a wafer/die transport tool 114 may be included in a multi-chamber (or cluster) deposition tool 102, which may include a pre-clean processing chamber (e.g., for cleaning or removing oxides, oxidation, and/or other types of contamination or byproducts from a substrate and/or semiconductor device) and a plurality of types of deposition processing chambers (e.g., processing chambers for depositing different types of materials, processing chambers for performing different types of deposition operations). In these implementations, the wafer/die transport tool 114 is configured to transport substrates and/or semiconductor devices between the processing chambers of the deposition tool 102 without breaking or removing a vacuum (or an at least partial vacuum) between the processing chambers and/or between processing operations in the deposition tool 102, as described herein.

In some implementations, one or more of the semiconductor processing tools 102-112 and/or the wafer/die transport tool 114 may perform one or more semiconductor processing operations described herein. For example, one or more of the semiconductor processing tools 102-112 and/or the wafer/die transport tool 114 may form a first electrode layer over a substrate; may form an interfacial layer on the first electrode layer, where the interfacial layer is formed such that the interfacial layer has a centrosymmetric crystal structure; may form a ferroelectric layer on the interfacial layer; and/or may form a second electrode layer over the ferroelectric layer.

As another examples, one or more of the semiconductor processing tools 102-112 and/or the wafer/die transport tool 114 may form a seed layer over a substrate; may form a first plurality of layers of an interfacial layer on the seed layer, where the seed layer promotes forming the interfacial layer to a grain size in a particular grain size range; and/or may form a second plurality of layers of a ferroelectric layer on the interfacial layer.

The number and arrangement of devices shown in FIG. 1 are provided as one or more examples. In practice, there may be additional devices, fewer devices, different devices, or differently arranged devices than those shown in FIG. 1. Furthermore, two or more devices shown in FIG. 1 may be implemented within a single device, or a single device shown in FIG. 1 may be implemented as multiple, distributed devices. Additionally, or alternatively, a set of devices (e.g., one or more devices) of the example environment 100 may perform one or more functions described as being performed by another set of devices of the example environment 100.

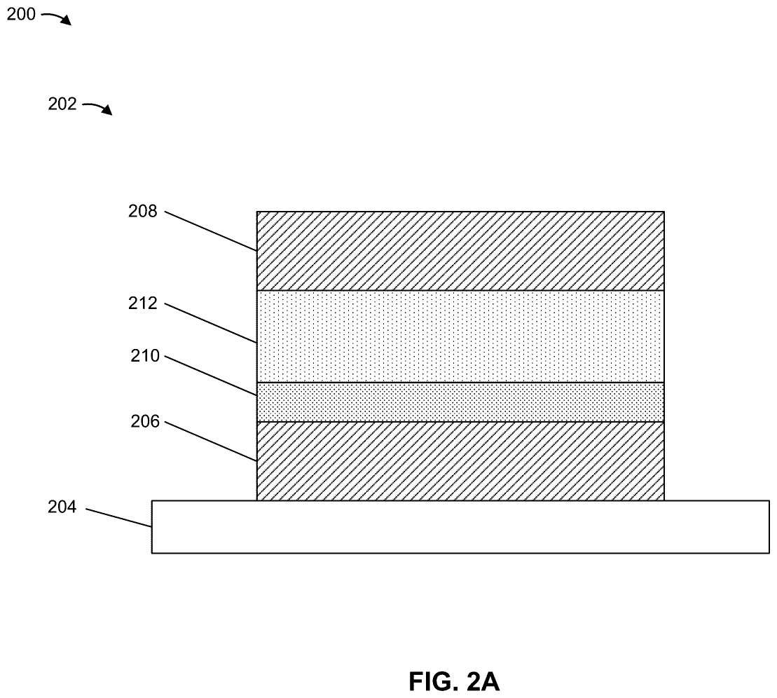

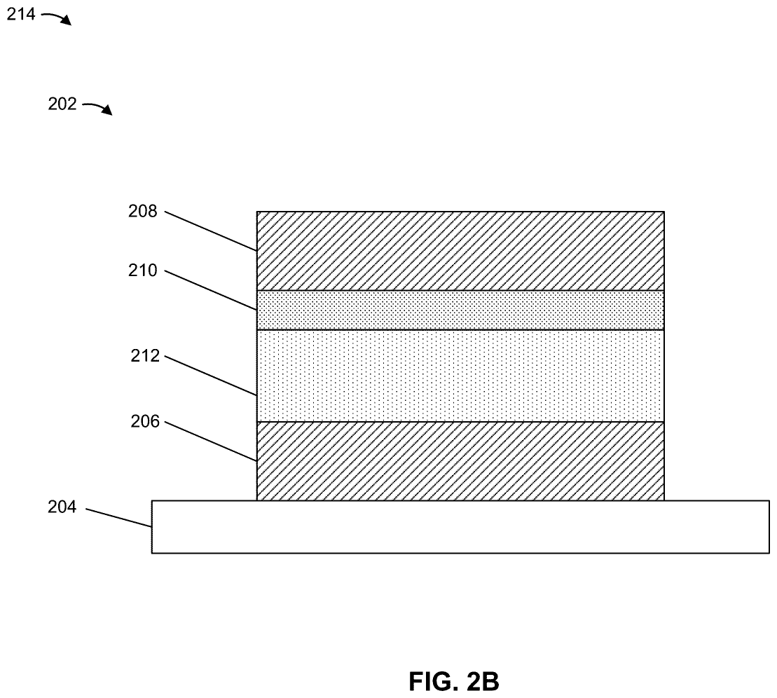

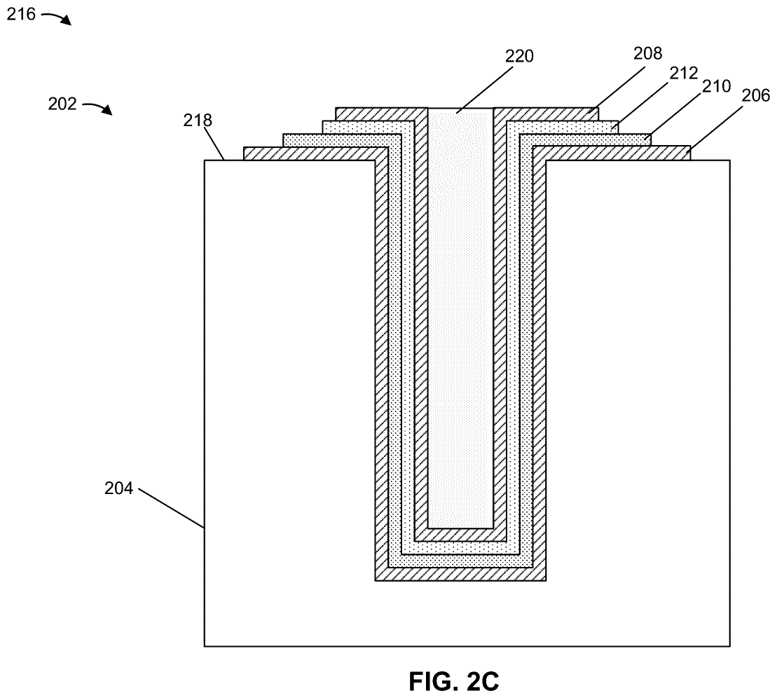

FIGS. 2A-2C are diagrams of example implementations of ferroelectric tunnel junction (FTJ) structures described herein. In some cases, an FTJ structure may include a metal-ferroelectric-metal (MFM) structure, including a ferroelectric (Fe) layer disposed between two metallic layers (e.g., electrodes). However, some FTJ structures may include metal-ferroelectric-interfacial-metal (MFIM) structure, where an interfacial layer (IL) is disposed between the ferroelectric layer and one of the metallic layers. The MFIM configuration in an FTJ structure may provide improved charge response in the FTJ structure relative to the MFM structure. Moreover, and as described herein, the interfacial layer may be formed in a manner that enables the ferroelectric layer to be formed to increase the formation of ferroelectric crystalline phases (e.g., orthorhombic crystalline phases) in the ferroelectric layer, and to reduce the formation of non-ferroelectric crystalline phases (e.g., monoclinic phases, tetragonal phases) in the ferroelectric layer.

FIG. 2A illustrates an example implementation 200 of an FTJ structure 202 described herein. The example implementation 200 of the FTJ structure 202 includes an approximately planar structure in which the FTJ structure 202 is arranged in an MFIM configuration. The example implementation 200 of the FTJ structure 202 includes a substrate 204, a bottom electrode 206 formed on the substrate 204, a top electrode 208 above and/or over the bottom electrode 206, an interfacial layer 210 between the bottom electrode 206 and the top electrode 208, and a ferroelectric layer 212 between the bottom electrode 206 and the top electrode 208. Moreover, in the example implementation 200 of the FTJ structure 202, the interfacial layer 210 is below and/or under the ferroelectric layer 212. Thus, in the example implementation 200 of the FTJ structure 202, the interfacial layer 210 is between the bottom electrode 206 and the ferroelectric layer 212, and the ferroelectric layer 212 is between the interfacial layer 210 and the top electrode 208.

The substrate 204 may include a semiconductor substrate, a substrate formed of a material including silicon, a III-V compound semiconductor material substrate such as gallium arsenide (GaAs), a silicon on insulator (SOI) substrate, a germanium (Ge) substrate, a silicon germanium (SiGe) substrate, a silicon carbide (SiC) substrate, or another type of semiconductor substrate.

The bottom electrode 206 and the top electrode 208 may each include one or more conductive materials, one or more semiconductive materials, and/or one or more of another type of material. For example, the bottom electrode 206 and the top electrode 208 may each include a metal, a metalloid, a metal alloy, and/or another type of metallic material. Examples include copper (Cu), cobalt (Co), ruthenium (Ru), titanium (Ti), tungsten (W), gold (Au), and/or silver (Ag), among other examples. In some implementations, the bottom electrode 206 and the top electrode 208 include the same material or the same combination of materials. In some implementations, the bottom electrode 206 and the top electrode 208 each include a different material or a different combination of materials.

The interfacial layer 210 may include a non-polar dielectric material having a centrosymmetric crystal structure. Examples include a tantalum oxide (e.g., Ta₂O₅), an aluminum oxide (e.g., Al₂O₃), a hafnium oxide (e.g., HfO₂), a silicon nitride (e.g., Si₃N₄), a lanthanum oxide (e.g., La₂O₃), and/or combinations thereof, among other examples. The ferroelectric layer 212 may include a polar dielectric material having a non-centrosymmetric crystal structure. Examples include a hafnium oxide (e.g., HfO or HfO₂), a zirconium oxide (e.g., ZrO₂), an HZO (e.g., Hf_{0.5}Zr_{0.5}O₂(HfZrO)), a hafnium silicon oxide (e.g., HfSiO), a hafnium lanthanum oxide (e.g., HfLaO), an aluminum scandium nitride (e.g., AlScN), a PBT (e.g., PbZrO₃), a PZT (e.g., Pb[ZrₓTi₁₋ₓ]O₃, (0≤x≤1)), a PLZT (e.g., Pb₁₋ₓLaₓZr_{1-y}Ti_{y}O₃), barium titanate (e.g., BaTiO₃), a lead titanate (e.g., PbTiO₃), a lead metaniobate (e.g., PbNb₂O₆), a lithium niobate (e.g., LiNbO₃), a lithium tantalate (e.g., LiTaO₃), a PMN (e.g., PbMg₁₋₃Nb_{2/3}O₃), a PST (e.g., PbSc_{1/2}Ta_{1/2}O₃), an SBT (e.g., SrBi₂Ta₂O₉), a BNT (e.g., Bi_{1/2}Na_{1/2}TiO₃), and/or combinations thereof, among other examples.

When the centrosymmetric (e.g., non-polar or non-ferroelectric) crystal structure of the interfacial layer 210 is located next to the non-centrosymmetric (e.g., polar or ferroelectric) crystal structure of the ferroelectric layer 212, FTJ operation can be realized. This configuration enables the ferroelectric layer 212 to be a ferroelectric switching layer. In particular, this configuration enables multiple current levels at the same voltage magnitude, depending on the remnant polarization of the ferroelectric layer 212 (e.g., the non-centrosymmetric layer). This creates multiple storage states in the FTJ structure 202, such as a low resistance state (LRS—which may correspond to a logical “1” value) and a high resistance state (HRS—which may correspond to a logical “0” value). These storage states may be achieved through band barrier height modulation. The polarity of the remnant polarization in the ferroelectric layer 212 controls the band bending direction. The unbalanced charge (e.g., which is dependent on the amount of dipoles and other properties of the interfacial layer 210) controls the magnitude of the band bending.

The material(s) of the ferroelectric layer 212 being crystallized in non-centrosymmetric phases increases the presence or concentration of ferroelectric phases (e.g., orthorhombic phases) in the ferroelectric layer 212. The non-centrosymmetric crystal structure, and thus spontaneous polarization that is capable of being generated in the ferroelectric layer 212, results in increased ferroelectric properties that can be obtained by the orthorhombic phases in the ferroelectric layer 212. The increased ferroelectric properties may include increased coercive field (E_{c}), increased remnant polarization (Pᵣ) area density, and/or increased polarization-electric field (P-E) hysteresis loop squareness, among other examples. As described herein, the interfacial layer 210 may be formed in a manner that enables the ferroelectric layer 212 to be formed to increase the formation of ferroelectric crystalline phases (e.g., orthorhombic crystalline phases) in the ferroelectric layer 212, and to reduce the formation of non-ferroelectric crystalline phases (e.g., monoclinic phases, tetragonal phases) in the ferroelectric layer 212. Thus, the techniques described herein may increase the ferroelectric properties of the ferroelectric layer 212, which may increase the performance and/or yield of FTJ structures 202 described herein.

FIG. 2B illustrates an example implementation 214 of an FTJ structure 202 described herein. The example implementation 214 of the FTJ structure 202 is similar to the example implementation 200 and includes the substrate 204, the bottom electrode 206, the top electrode 208, the interfacial layer 210, and the ferroelectric layer 212. However, in the example implementation 214 of the FTJ structure 202, the interfacial layer 210 is above and/or over the ferroelectric layer 212. Thus, in the example implementation 214 of the FTJ structure 202, the ferroelectric layer 212 is between the bottom electrode 206 and the interfacial layer 210, and the interfacial layer 210 is between the ferroelectric layer 212 and the top electrode 208.

FIG. 2C illustrates an example implementation 216 of an FTJ structure 202 described herein. The example implementation 216 of the FTJ structure 202 is similar to the example implementation 200 and includes the substrate 204, the bottom electrode 206, the top electrode 208, the interfacial layer 210, and the ferroelectric layer 212. However, in the example implementation 216 of the FTJ structure 202, the bottom electrode 206, the top electrode 208, the interfacial layer 210, and the ferroelectric layer 212 are arranged in a trench configuration (e.g., a deep trench configuration). In this configuration, the bottom electrode 206, the top electrode 208, the interfacial layer 210, and the ferroelectric layer 212 extend from a top surface 218 of the substrate 204 into the substrate 204 below the top surface 218. A trench may be formed into the substrate 204 from the top surface 218, and the bottom electrode 206, the top electrode 208, the interfacial layer 210, and the ferroelectric layer 212 may be deposited in a conformal manner. In this way, the bottom electrode 206, the top electrode 208, the interfacial layer 210, and the ferroelectric layer 212 conform to the shape of the trench in the substrate 204. A dielectric filler 220 may fill the remaining area in the trench.

As indicated above, FIGS. 2A-2C are provided as examples. Other examples may differ from what is described with regard to FIGS. 2A-2C. For example, the bottom electrode 206, the top electrode 208, the interfacial layer 210, and the ferroelectric layer 212 may be arranged in another type of configuration, such as a crown type configuration, a via type configuration, and/or another type of configuration.

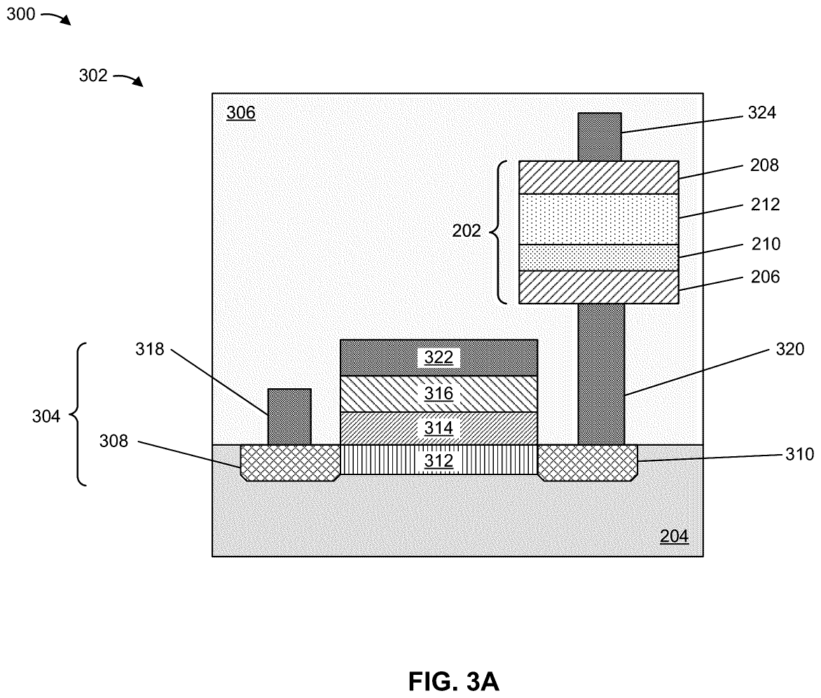

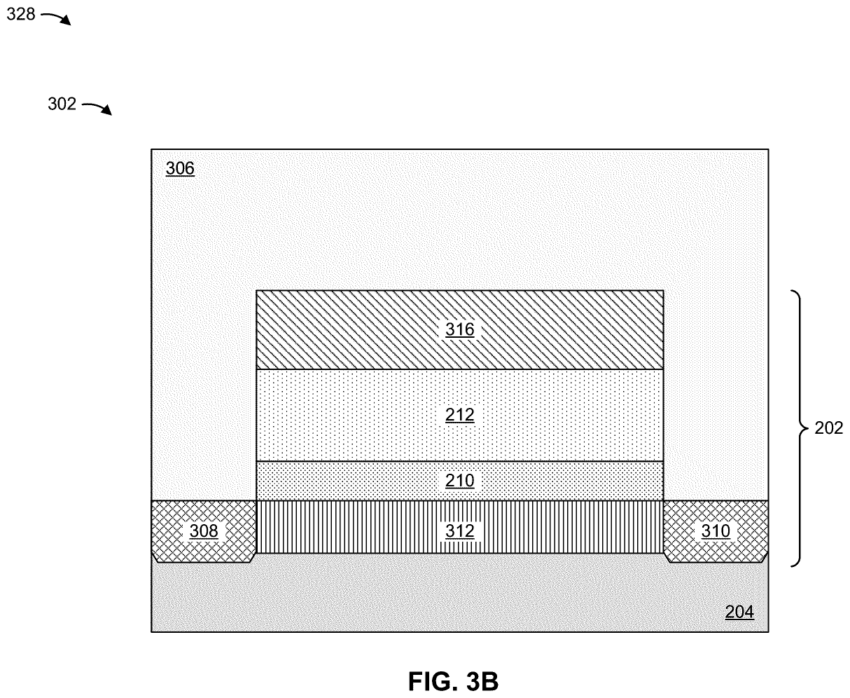

FIGS. 3A and 3B are diagrams of example implementations of ferroelectric random access memory (FeRAM) cell structures described herein. The example implementations of the FeRAM cell structures described in connection with FIGS. 3A and 3B may include an FTJ structure 202 (or a portion thereof) described in connection with one or more of FIGS. 2A-2C.

FIG. 3A illustrates an example implementation 300 of a memory cell structure 302. In the example implementation 300, the memory cell structure 302 includes an example of an FeRAM cell that includes a transistor 304 and an FTJ structure 202 electrically connected with the transistor 304. The transistor may include a planar transistor, a fin field effect transistor (FinFET), a nanostructure transistor (e.g., a nanosheet transistor, a nanowire transistor, a gate all around (GAA) transistor), and/or another type of transistor.

The transistor 304 may be disposed on the substrate 204. The transistor 304 and the FTJ structure 202 may be surrounded by a dielectric layer 306. The dielectric layer 306 may include one or more other types of dielectric materials and/or insulating materials, such as a nitride, a silicon nitride (SiₓN_{y}), a silicon oxynitride (SiON), fluoride-doped silicate glass (FSG), a low dielectric constant (low-k) dielectric material, and/or another suitable electrically insulating material.

The transistor 304 may include an active region (sometimes referred to as an operating domain (OD)) that includes a source/drain region 308, a source/drain region 310, and a semiconductive channel 312 between the source/drain regions 308 and 310. The source/drain region 308, the source/drain region 310, and the semiconductive channel 312 may be included in the substrate 204. Source/drain region(s) may refer to a source or a drain, individually or collectively dependent upon the context. In some implementations, the substrate 204 includes polysilicon, amorphous silicon, a semiconducting oxide, or another semiconductive material. In these implementations, the transistor 304 may be a complementary metal oxide semiconductor (CMOS) transistor. In some implementations, the substrate 204 includes an amorphous silicon or polysilicon substrate. In these implementations, the transistor 304 may be a thin-film transistor (TFT). In some implementations, the substrate 204 includes a layer formed during a back end of line (BEOL) process. In these implementations, the transistor 304 may be a BEOL transistor).

A dielectric layer 314 may be disposed on the semiconductive channel 312 (e.g., on the channel layer of the transistor 304). The dielectric layer 314 may include a high dielectric constant (high-k) dielectric material and may correspond to a gate oxide or gate dielectric layer of the transistor 304. A gate electrode 316 may be disposed on the dielectric layer 314. The gate electrode 316 may be formed of any suitable electrically conductive material, using any suitable deposition process, as described herein.

The source/drain region 308 may be electrically connected and/or physically connected with a bit line conductive structure 318. The source/drain region 310 may be electrically connected and/or physically connected with the bottom electrode 206 of the FTJ structure 202. In some implementations, the source/drain region 310 is electrically connected with the bottom electrode 206 of the FTJ structure 202 by a drain via contact structure 320. In some implementations, the source/drain region 310 is electrically connected and/or physically connected directly with the bottom electrode 206 of the FTJ structure 202. The gate electrode 316 may be electrically connected and/or physically connected with a word line conductive structure 322. The top electrode 208 of the FTJ structure 202 may be electrically connected and/or physically connected with a plate line conductive structure 324.

FIG. 3B illustrates an example implementation 328 of a memory cell structure 302. In the example implementation 328, the memory cell structure 302 includes an example of an FeRAM cell that includes an FeFET in which the FTJ structure 202 is included as part of a transistor. The FeFET includes the source/drain regions 308 and 310, the semiconductive channel 312 in the substrate 204, the interfacial layer 210 over the semiconductive channel 312, the ferroelectric layer 212 over the interfacial layer 210, and the gate electrode 316 over the ferroelectric layer 212. The dielectric layer 306 may be included over the FeFET. The semiconductive channel 312 may correspond to the bottom electrode 206 of the FTJ structure 202, and the gate electrode 316 may correspond to the top electrode 208 of the FTJ structure 202.

To transition the FeFET to a programmed state, a positive gate voltage (+V_{G}) may be applied to the gate electrode 316. This electron charge carriers in electron/hole pairs in the ferroelectric layer 212 to be biased toward the gate electrode 316. A 0 voltage (0V) may be applied to the source/drain region 308, and the source/drain region 310 may be grounded. This causes the semiconductive channel 312 to be in a non-conductive state, thereby causing hole charge carriers in the electron/hole pairs of the ferroelectric layer 212 to be biased toward the semiconductive channel 312.

To transition the FeFET to an erased state, a negative gate voltage (−V_{G}) may be applied to the gate electrode 316. A 0 voltage (0V) may be applied to the source/drain region 308, and the source/drain region 310 may be grounded. This causes the semiconductive channel 312 to be in a non-conductive state. This causes the hole charge carriers in electron/hole pairs in the ferroelectric layer 212 to be biased toward the gate electrode 316, and causes the electron charge carriers in the electron/hole pairs of the ferroelectric layer 212 to be biased toward the semiconductive channel 312.

As indicated above, FIGS. 3A and 3B are provided as examples. Other examples may differ from what is described with regard to FIGS. 3A and 3B.

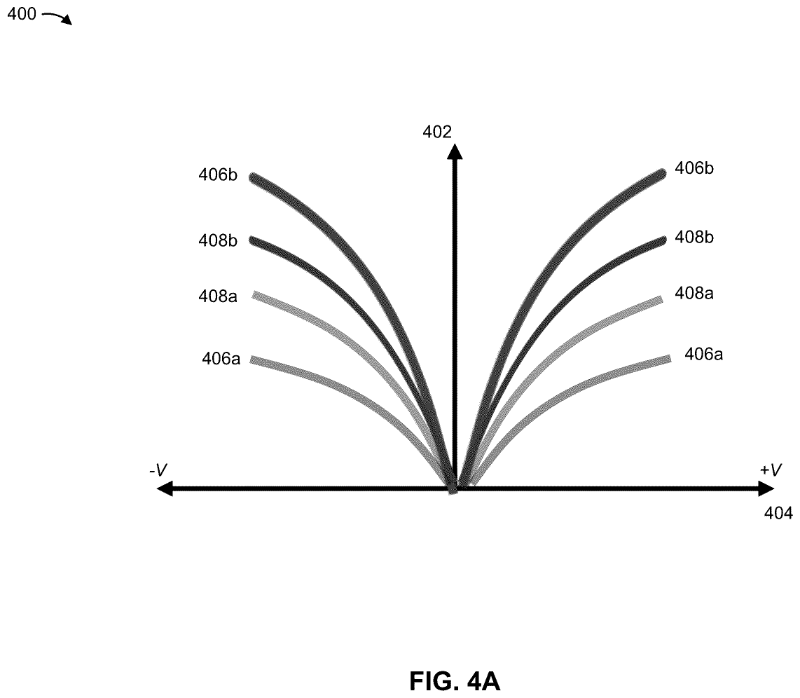

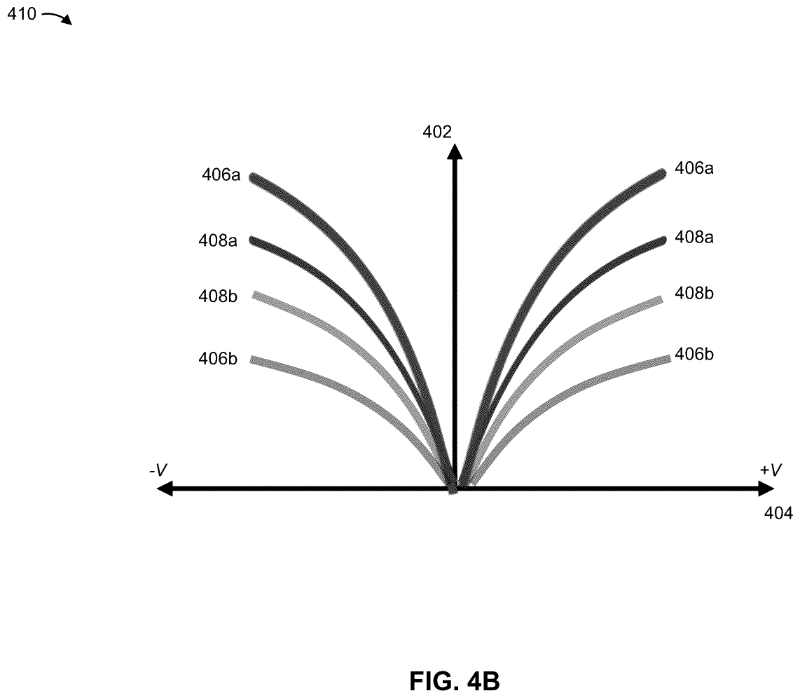

FIGS. 4A and 4B are diagrams of example implementations of current distributions of FTJ structures described herein.

FIG. 4A illustrates an example implementation 400 of current distributions of an FTJ structure 202 in which the interfacial layer 210 is below and/or under the ferroelectric layer 212. This configuration may correspond to the example implementation 200 of the FTJ structure 202 illustrated in FIG. 2A. The current distributions are illustrated as a function of current 402 and voltage 404.

Current distributions 406a and 406b are example current distributions in implementations in which the interfacial layer 210 includes a low-k non-polar (or centrosymmetric) dielectric material, whereas the current distributions 408a and 408b are example current distributions in implementations in which the interfacial layer 210 includes a high-k non-polar (or centrosymmetric) dielectric material. The current distributions 406a and 408a correspond a negative remnant polarization in the ferroelectric layer 212, whereas the current distributions 406b an 408b correspond a positive remnant polarization in the ferroelectric layer 212.

Due to the vertical arrangement of the interfacial layer 210 and the ferroelectric layer 212 illustrated in FIG. 2A, the ferroelectric layer 212 is in a high resistance state (HRS) when the ferroelectric layer 212 includes a positive remnant polarization (corresponding to the current distributions 406b an 408b in FIG. 4A), and is in a low resistance state (LRS) when the ferroelectric layer 212 includes a negative remnant polarization (corresponding to the current distributions 406a an 408a in FIG. 4A).

As shown by the current distributions 406a, 406b, 408a, and 408b, the FTJ structure 202 generally exhibits a larger magnitude of current flow when the ferroelectric layer 212 is in the low resistance state relative to the magnitude of current flow when the ferroelectric layer 212 is in the high resistance state. As shown by the current distributions 406a, 406b, 408a, and 408b, a low-k non-polar (or centrosymmetric) dielectric material for the interfacial layer 210 (which is associated with the current distributions 406a and 406b) provides a greater difference in current magnitude (and thus, a greater resistance ratio) between the high resistance state and the low resistance state in the ferroelectric layer 212 relative to a high-k non-polar (or centrosymmetric) dielectric material for the interfacial layer 210 (which is associated with the current distributions 408a and 408b).

FIG. 4B illustrates an example implementation 410 of a current distribution of an FTJ structure 202 in which the interfacial layer 210 is above and/or over the ferroelectric layer 212. This configuration may correspond to the example implementation 214 of the FTJ structure 202 illustrated in FIG. 2B. Due to the reversed vertical arrangement of the interfacial layer 210 and the ferroelectric layer 212 illustrated in FIG. 2B relative to FIG. 2A, the ferroelectric layer 212 is in a low resistance state (LRS) when the ferroelectric layer 212 includes a positive remnant polarization (corresponding to the current distributions 406b an 408b in FIG. 4B), and is in a high resistance state (HRS) when the ferroelectric layer 212 includes a negative remnant polarization (corresponding to the current distributions 406a an 408a in FIG. 4B).

As indicated above, FIGS. 4A and 4B are provided as examples. Other examples may differ from what is described with regard to FIGS. 4A and 4B.

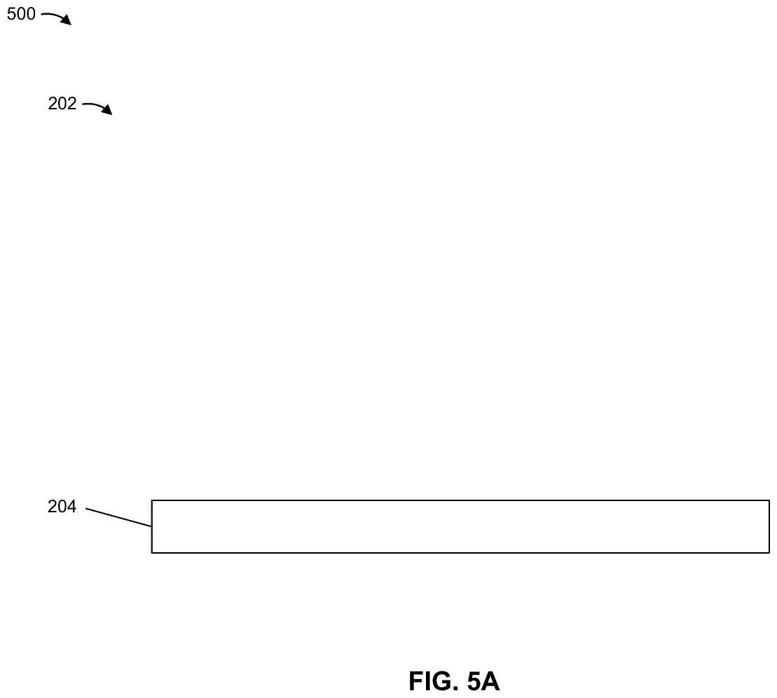

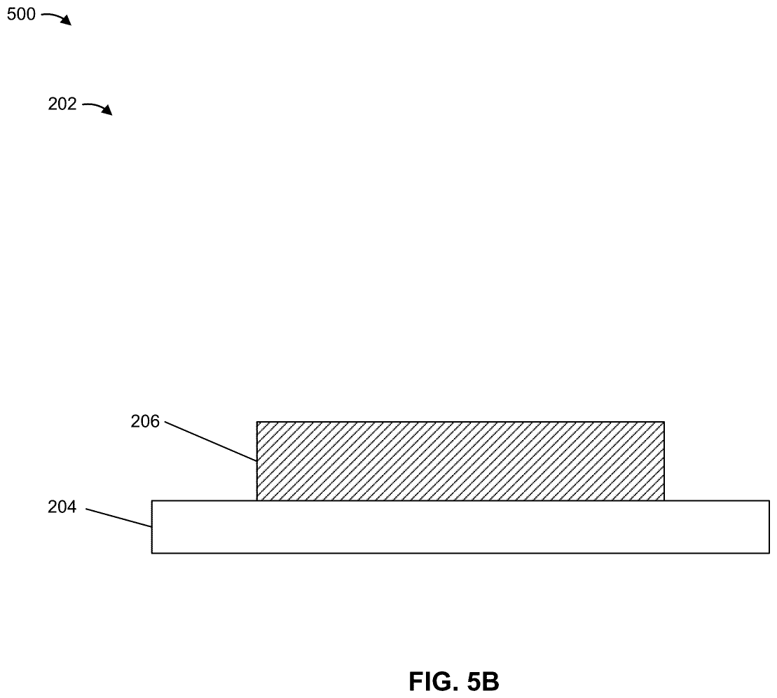

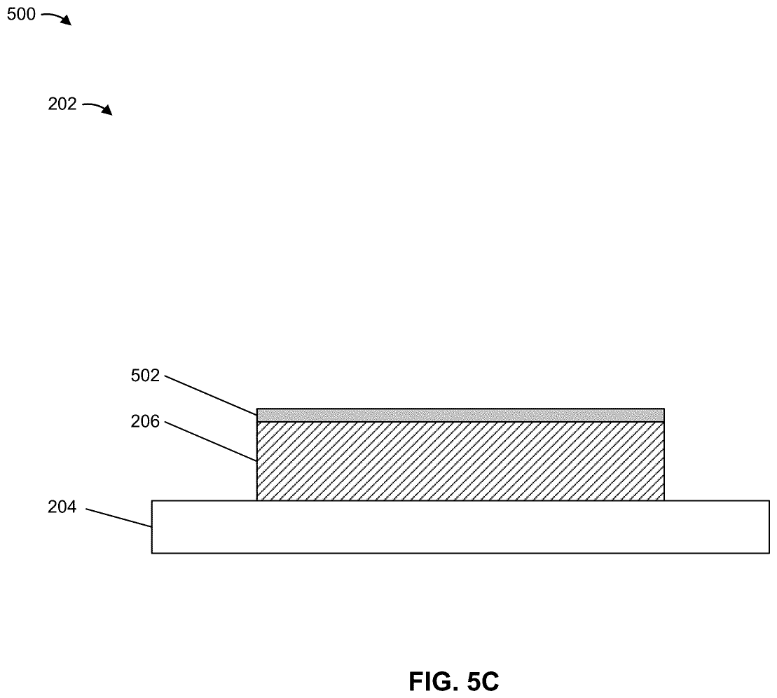

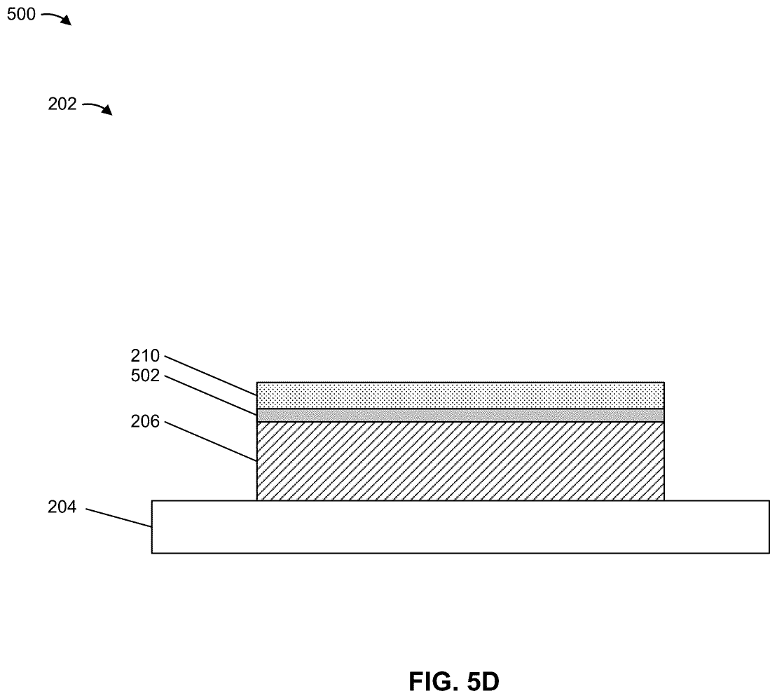

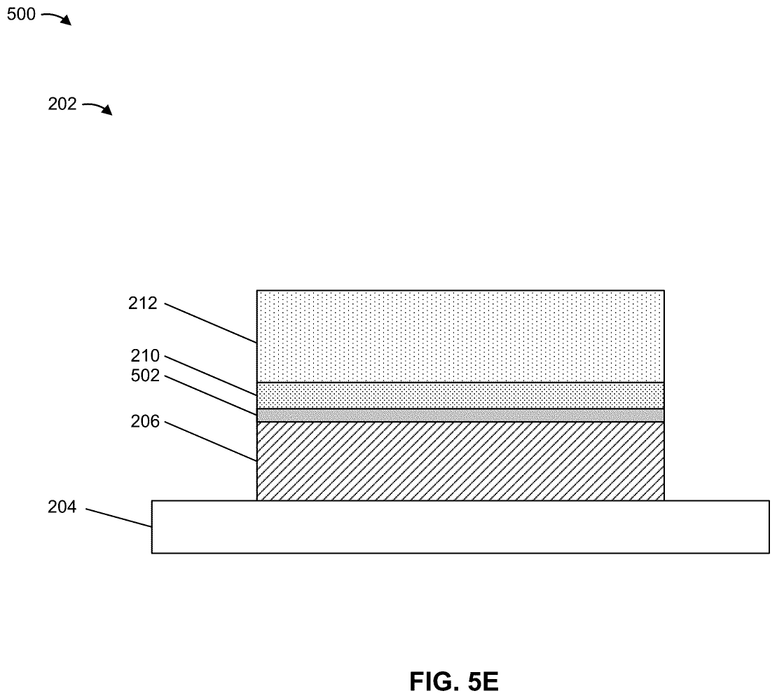

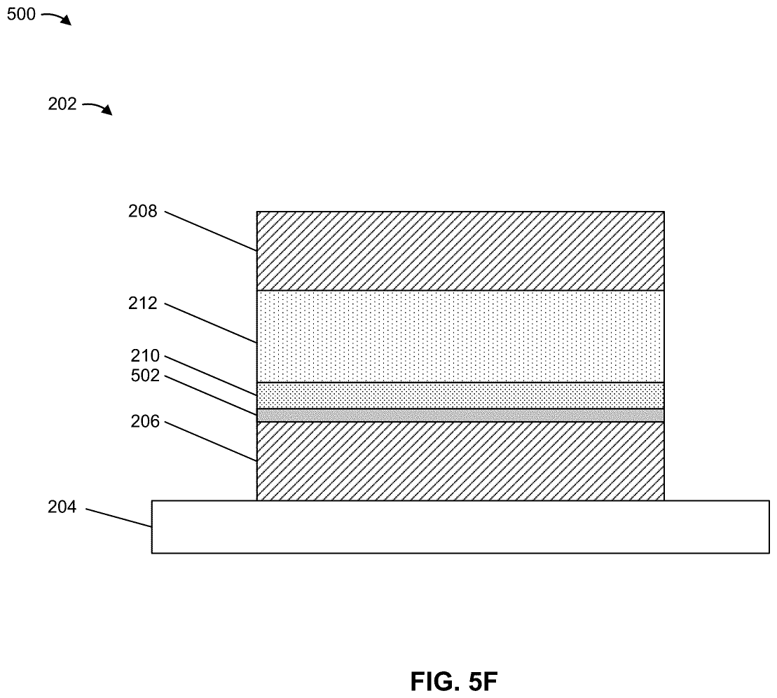

FIGS. 5A-5F are diagrams of an example implementation 500 of forming an FTJ structure 202 described herein. In some implementations, the operations described in the example implementation 500 may be performed as part of a semiconductor manufacturing process to form an FeFET, an FeRAM cell (e.g., a memory cell structure 302 described herein), and/or another type of semiconductor device. In some implementations, one or more of the operations described in the example implementation 500 may be performed by one or more of the semiconductor processing tools 102-112 and/or the wafer/die transport tool 114 illustrated in FIG. 1. In some implementations, one or more of the operations described in the example implementation 500 may be performed by another semiconductor processing tool.

As shown in FIG. 5A, the operations described in the example implementation 500 may be performed in connection with the substrate 204. In some implementations, the substrate 204 is provided in the form of a semiconductor wafer or another semiconductor work piece. In some implementations, the substrate 204 is provided to a processing chamber of a semiconductor processing tool.

As shown in FIG. 5B, a bottom electrode 206 may be formed over and/or on the substrate 204. The deposition tool 102 and/or the plating tool 112 may deposit the bottom electrode 206 using a CVD technique, a PVD technique, an ALD technique, an electroplating technique, another deposition technique described above in connection with FIG. 1, and/or a deposition technique other than as described above in connection with FIG. 1. In some implementations, the planarization tool 110 may perform a CMP operation to planarize the bottom electrode 206 after the bottom electrode 206 is deposited.

As shown in FIG. 5C, a seed layer 502 is formed over and/or on the bottom electrode 206. The deposition tool 102 may deposit the seed layer 502 using an epitaxy technique, a CVD technique, a PVD technique, an ALD technique, another deposition technique described above in connection with FIG. 1, and/or a deposition technique other than as described above in connection with FIG. 1.

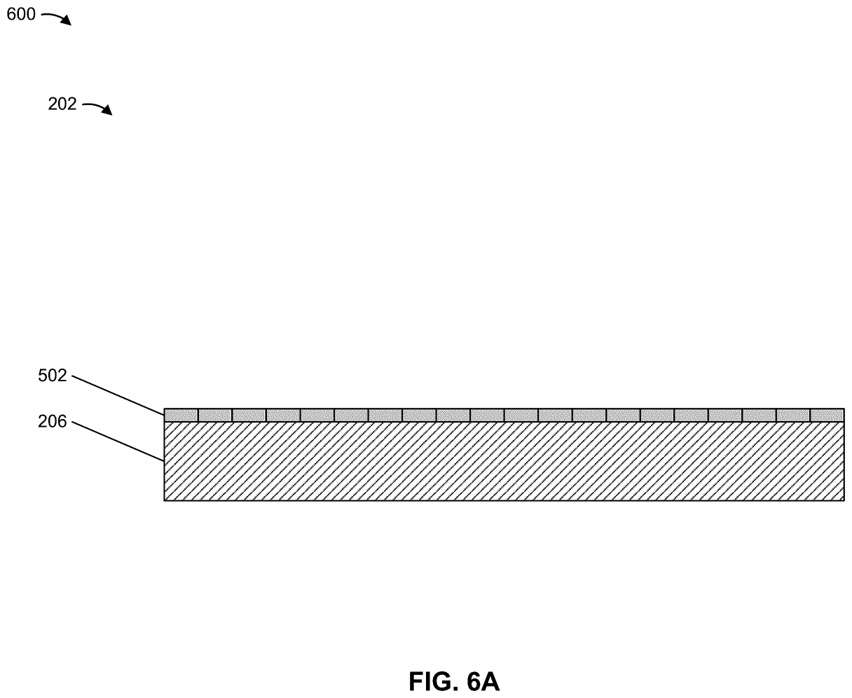

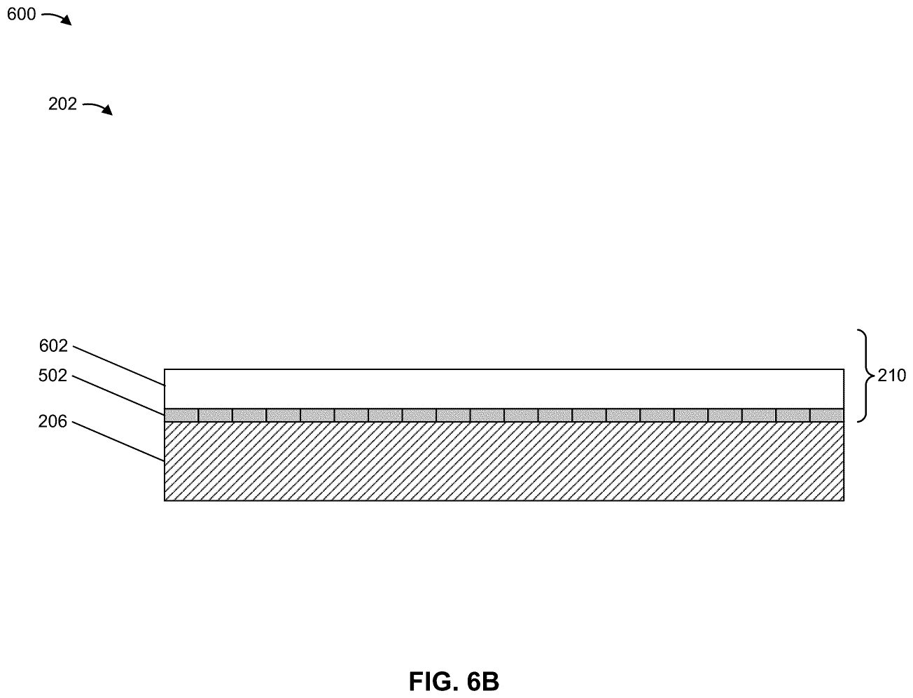

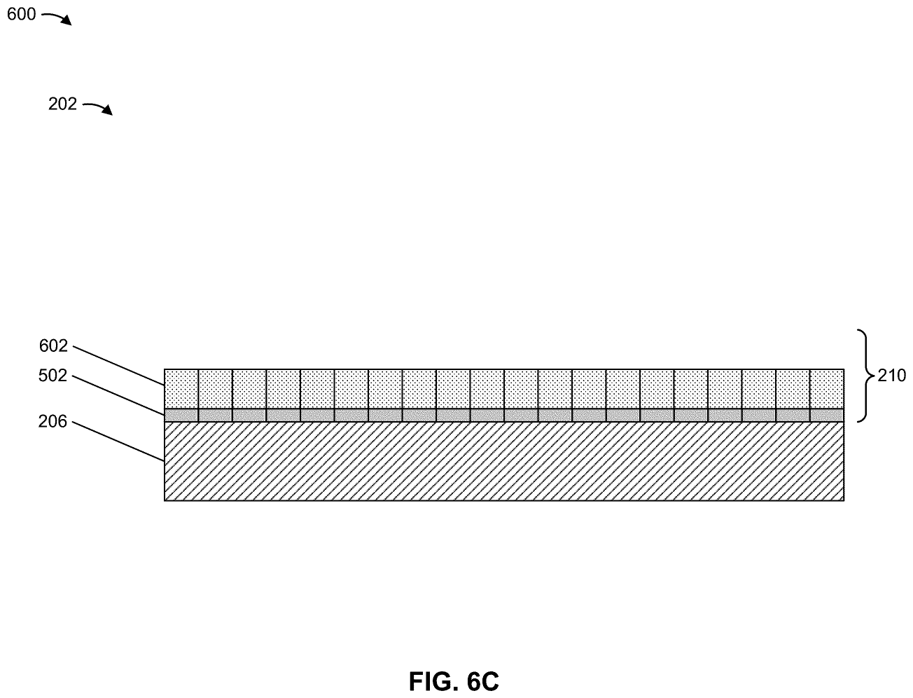

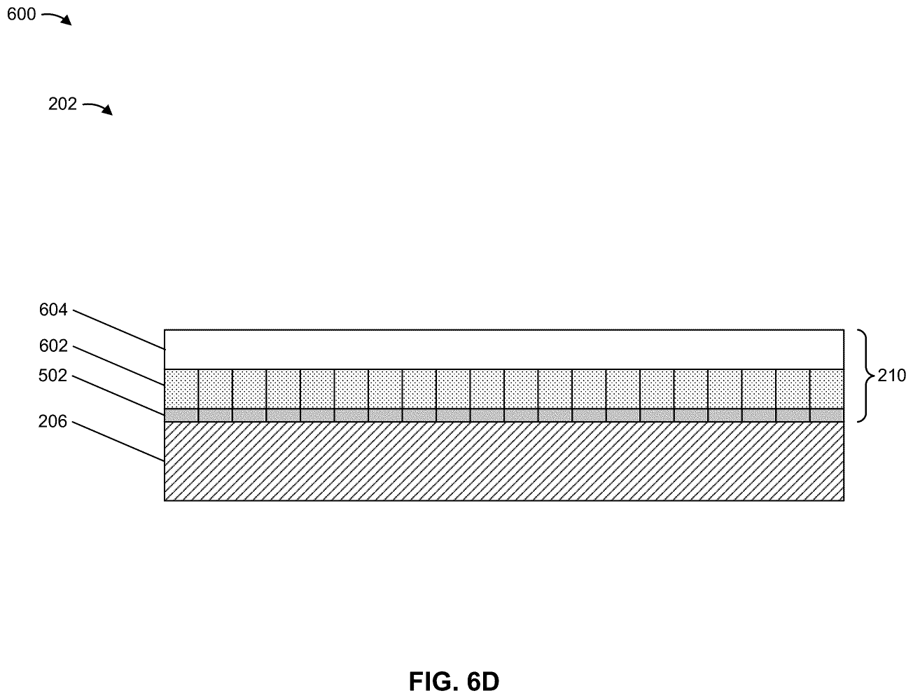

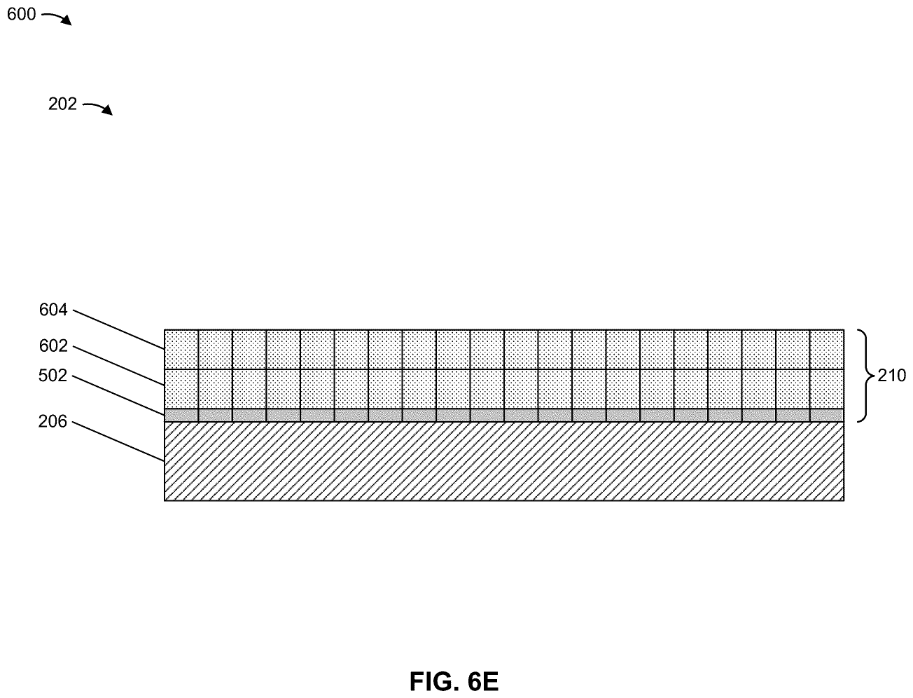

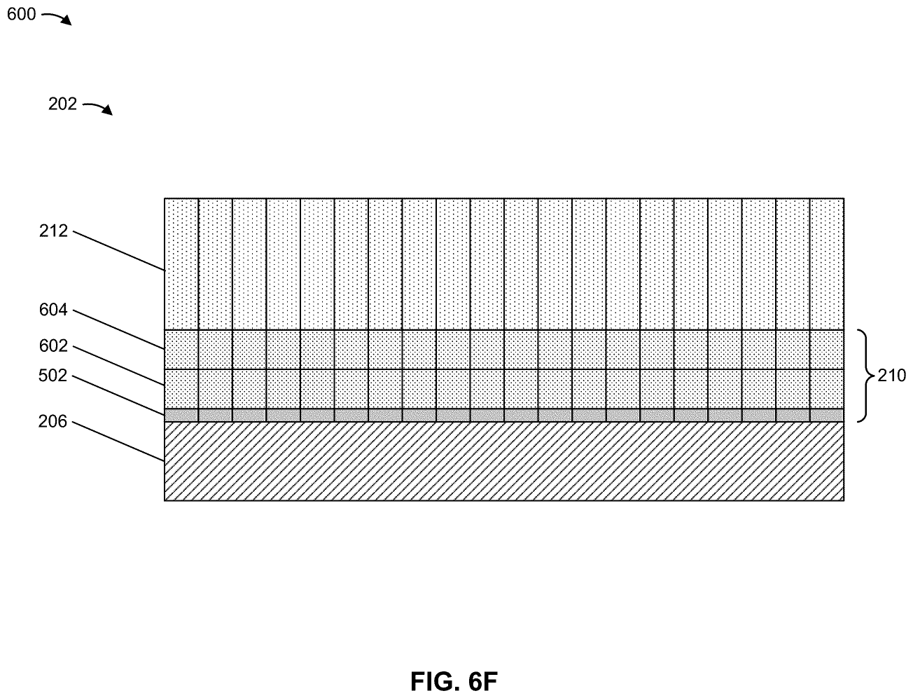

As shown in FIG. 5D, an interfacial layer 210 is formed over the bottom electrode 206 and on the seed layer 502. The seed layer 502 facilitates growth of the interfacial layer 210 in a particular crystal structure and/or to a particular grain size. The deposition tool 102 may deposit the interfacial layer 210 using an epitaxy technique, a CVD technique, a PVD technique, an ALD technique, another deposition technique described above in connection with FIG. 1, and/or a deposition technique other than as described above in connection with FIG. 1. The interfacial layer 210 may be formed using techniques described in connection with FIGS. 6A-6F. In some implementations, the planarization tool 110 may perform a CMP operation to planarize the interfacial layer 210 after the interfacial layer 210 is formed. In some implementations, the seed layer 502 and the interfacial layer 210 include a same material or a same combination of materials. In some implementations, the seed layer 502 and the interfacial layer 210 include different materials or a different combination of materials. In some implementations, the interfacial layer 210 includes a material that has a dielectric constant that is included in a range of approximately 5 to approximately 50 to achieve a sufficiently high tunnel current for the FTJ structure 202 while achieving a sufficiently low capacitance in the interfacial layer 210. However, other values for the range are within the scope of the present disclosure.

As shown in FIG. 5E, a ferroelectric layer 212 is formed over and/or on the interfacial layer 210. The deposition tool 102 may deposit the ferroelectric layer 212 using an epitaxy technique, a CVD technique, a PVD technique, an ALD technique, another deposition technique described above in connection with FIG. 1, and/or a deposition technique other than as described above in connection with FIG. 1. The ferroelectric layer 212 may be formed using techniques described in connection with FIGS. 6A-6F. In some implementations, the planarization tool 110 may perform a CMP operation to planarize the ferroelectric layer 212 after the ferroelectric layer 212 is formed. In some implementations, the ferroelectric layer 212 includes a material that has a dielectric constant that is included in a range of approximately 15 to approximately 60 to achieve a crystalline structure for the ferroelectric layer 212. However, other values for the range are within the scope of the present disclosure.

As shown in FIG. 5F, a top electrode 208 may be formed over and/or on the ferroelectric layer 212. The deposition tool 102 and/or the plating tool 112 may deposit the top electrode 208 using a CVD technique, a PVD technique, an ALD technique, an electroplating technique, another deposition technique described above in connection with FIG. 1, and/or a deposition technique other than as described above in connection with FIG. 1. In some implementations, the planarization tool 110 may perform a CMP operation to planarize the top electrode 208 after the top electrode 208 is deposited.

As indicated above, FIGS. 5A-5F are provided as an example. Other examples may differ from what is described with regard to FIGS. 5A-5F.

FIGS. 6A-6F are diagrams of an example implementation 600 of forming an FTJ structure 202 described herein. In particular, the example implementation 600 may include an example of forming an interfacial layer 210 and a ferroelectric layer 212 of the FTJ structure 202. In some implementations, the operations described in the example implementation 600 may be performed as part of a semiconductor manufacturing process to form an FeFET, an FeRAM cell (e.g., an FeRAM cell 302 described herein), and/or another type of semiconductor device. In some implementations, one or more of the operations described in the example implementation 600 may be performed by one or more of the semiconductor processing tools 102-112 and/or the wafer/die transport tool 112 illustrated in FIG. 1. In some implementations, one or more of the operations described in the example implementation 600 may be performed by another semiconductor processing tool.

As shown in FIG. 6A, the deposition tool 102 may deposit the seed layer 502 to enable control over formation of the crystal structure and grain size of the seed layer 502. In particular, the deposition tool 102 may deposit the seed layer 502 using a sputtering technique or another type of PVD technique such that the seed layer 502 is formed to a greater thickness than if the seed layer 502 were formed using an ALD technique or another similar deposition technique. The greater thickness of the seed layer 502 promotes forming the interfacial layer 210 to a grain size in a particular grain size range. In particular, the greater thickness of the seed layer 502 results in formation of a larger grain size in the seed layer 502.

As shown in FIG. 6B-6E, forming the interfacial layer 210 may include forming a plurality of layers to grow the interfacial layer 210 in a highly controlled manner to control the grain size in the interfacial layer 210. The plurality of layers may be formed by performing a cyclic process that includes a plurality of cycles of a deposition operation and an annealing operation.

As shown in FIG. 6B, a layer 602 of the interfacial layer 210 may be formed over and/or on the seed layer 502. The deposition tool 102 may deposit the layer 602 using an epitaxy technique, a CVD technique, a PVD technique, an ALD technique, another deposition technique described above in connection with FIG. 1, and/or a deposition technique other than as described above in connection with FIG. 1.

As shown in FIG. 6C, the layer 602 may be annealed in an annealing operation in the deposition tool 102 after the layer 602 is formed. The layer 602 may be deposited as an amorphous structure prior to the annealing operation. Annealing the layer 602 causes the amorphous structure to be transformed to a crystal structure (e.g., centrosymmetric crystal structure) in the layer 602. The crystal structure of the layer 602 may conform to a crystal structure of the seed layer 502, which causes the grain size of the interfacial layer 210 to conform to (or at least be influenced by) the grain size of the seed layer 502.

As shown in FIG. 6D, a layer 604 of the interfacial layer 210 may be formed over and/or on the layer 602 after the layer 602 is annealed. The deposition tool 102 may deposit the layer 604 using an epitaxy technique, a CVD technique, a PVD technique, an ALD technique, another deposition technique described above in connection with FIG. 1, and/or a deposition technique other than as described above in connection with FIG. 1.

As shown in FIG. 6E, the layer 604 may be annealed in an annealing operation in the deposition tool 102 after the layer 604 is formed. The layer 604 may be deposited as an amorphous structure prior to the annealing operation. Annealing the layer 604 causes the amorphous structure to be transformed to a crystal structure (e.g., centrosymmetric crystal structure) in the layer 604. The crystal structure of the layer 604 may conform to a crystal structure of the layer 602, which causes the grain size of the interfacial layer 210 to conform to (or at least be influenced by) the grain size of the layer 602. The cyclic process of depositing and annealing layers of the interfacial layer 210 facilitates formation of a highly consistent and uniform gain size in the interfacial layer 210.

The quantity of deposition and annealing cycles illustrated in FIGS. 6B-6E may be selected such that the interfacial layer 210 is formed to have a grain size that promotes formation of an orthorhombic phase in the ferroelectric layer 212. In particular, the interfacial layer 210 may be formed to a grain size that is included in a range of approximately 2 nanometers to approximately 10 nanometers to promote or facilitate formation of the ferroelectric layer 212 such that the ferroelectric layer 212 has a grain size that promotes formation of an orthorhombic phase in the ferroelectric layer 212 and resists formation of a tetragonal phase and a monoclinic phase in the ferroelectric layer 212. However, other values for the range are within the scope of the present disclosure.

The quantity of deposition and annealing cycles illustrated in FIGS. 6B-6E may be selected such that the interfacial layer 210 is formed to a particular thickness or thickness range. In some implementations, the interfacial layer 210 is formed to a thickness that is included in a range of approximately 0.5 nanometers to approximately 3 nanometers to enable the interfacial layer 210 to be formed without voids or other discontinuities while achieving a relatively low capacitance in the interfacial layer 210 and relatively low switching voltage for the FTJ structure 202. Achieving a relatively low capacitance for the interfacial layer 210 may provide a sufficiently high depolarization field (E_{dep}) for the FTJ structure 202, which may increase the band bending of the band diagram of the FTJ structure 202 and may provide a greater resistance ratio. However, other values for the range are within the scope of the present disclosure.

As shown in FIG. 6F, the ferroelectric layer 212 may be formed over and/or on the interfacial layer 210 (e.g., over and/or on the layer 604 of the interfacial layer 210). The ferroelectric layer 212 may be formed after the layer 604 is annealed. The deposition tool 102 may deposit the ferroelectric layer 212 using an epitaxy technique, a CVD technique, a PVD technique, an ALD technique, another deposition technique described above in connection with FIG. 1, and/or a deposition technique other than as described above in connection with FIG. 1. In some implementations, the ferroelectric layer 212 is deposited as a plurality of layers (e.g., using an ALD technique and/or another suitable deposition technique).

As shown in FIG. 6F, the crystal structure of the ferroelectric layer 212 may conform to a crystal structure of the interfacial layer 210, which causes the grain size of the ferroelectric layer 212 to conform to (or at least be influenced by) the grain size of the interfacial layer 210. In some implementations, the ferroelectric layer 212 is formed such that the grain size of the ferroelectric layer 212 is included in a range of approximately 2 nanometers to approximately 15 nanometers to promote formation of an orthorhombic phase (e.g., a ferroelectric phase) in the ferroelectric layer 212 and to resist formation of a tetragonal phase and a monoclinic phase in the ferroelectric layer 212. However, other values for the range are within the scope of the present disclosure. In some implementations, the ferroelectric layer 212 is formed to a thickness that is included in a range of approximately 0.5 nanometers to approximately 4 nanometers to enable the ferroelectric layer 212 to be formed without voids or other discontinuities while achieving a relatively low capacitance in the ferroelectric layer 212 and relatively low switching voltage for the FTJ structure 202. However, other values for the range are within the scope of the present disclosure.

As indicated above, FIGS. 6A-6F are provided as an example. Other examples may differ from what is described with regard to FIGS. 6A-6F.

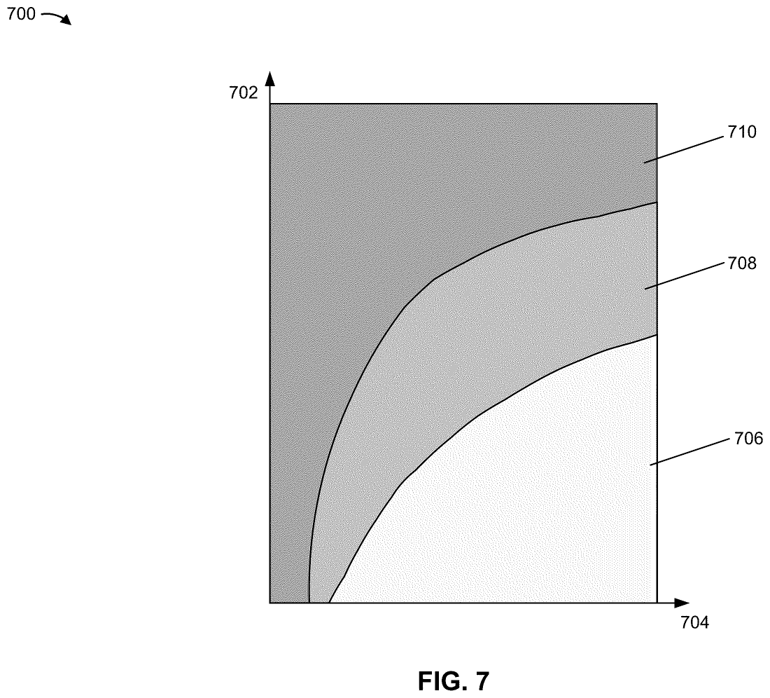

FIG. 7 is a diagram of an example implementation 700 of phase composition of a ferroelectric layer 212 of an FTJ structure 202 described herein. The phase composition is illustrated in FIG. 7 as a function of zirconium concentration 702 in the ferroelectric layer 212 and a grain size 704 of the ferroelectric layer 212. The phase composition includes a monoclinic (non-ferroelectric) phase 706, an orthorhombic (ferroelectric) phase 708, and a tetragonal (non-ferroelectric) phase 710.

As shown in FIG. 7, the concentration or presence of the orthorhombic phase 708 in the ferroelectric layer 212 may be increased by increasing the zirconium concentration 702 in the ferroelectric layer 212, by increasing the grain size 704 of the ferroelectric layer 212, or a combination thereof. As described herein, the interfacial layer 210 of the FTJ structure 202 may be formed in a manner that enables the grain size 704 of the ferroelectric layer 212 to be highly controlled to increase the formation of the orthorhombic phase 708 in the ferroelectric layer 212 using the techniques described herein. The techniques described herein may enable the ferroelectric layer 212 to be formed to a larger grain size 704 while achieving a non-centrosymmetric crystal structure in the ferroelectric layer 212. The combination of larger grain size 704 and non-centrosymmetric crystal structure enables the FTJ structure 202 to operate based on ferroelectric switching principles while increasing the remnant polarization area density in the ferroelectric layer 212, which increases the memory window size for the FTJ structure 202.

As indicated above, FIG. 7 is provided as an example. Other examples may differ from what is described with regard to FIG. 7.

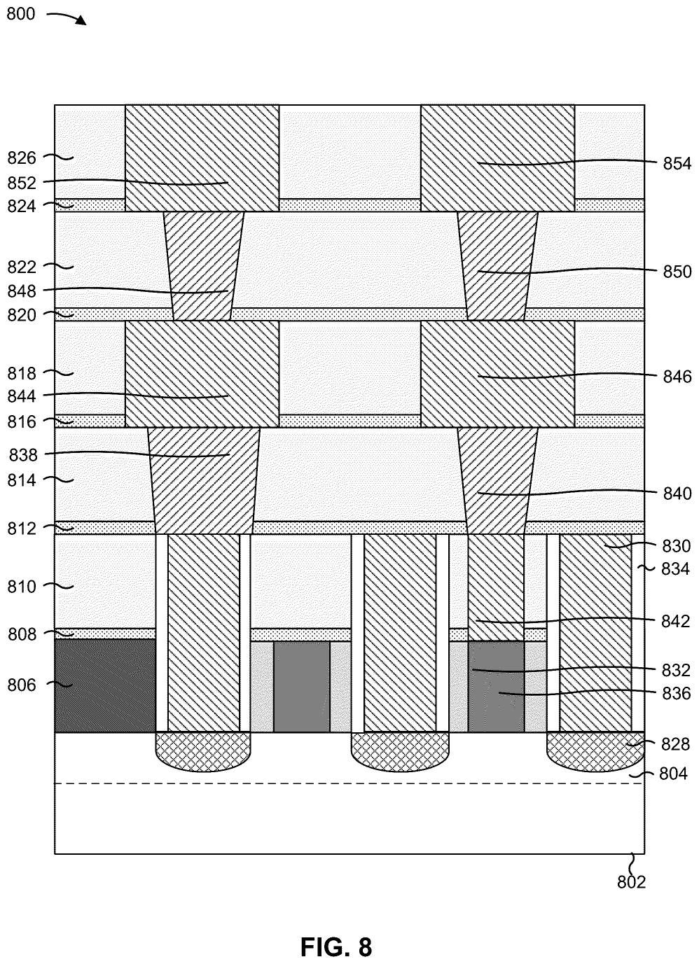

FIG. 8 is a diagram of a portion of an example device 800 described herein. Device 800 includes an example of a memory device (e.g., a static random access memory (SRAM), a dynamic random access memory (DRAM)), a logic device, a processor, an input/output device, or another type of semiconductor device that includes one or more transistors.

The device 800 includes a substrate 802 and a fin structure 804 that extends above the substrate 802. The device 800 includes one or more stacked layers, including a dielectric layer 806, an etch stop layer (ESL) 808, a dielectric layer 810, an ESL 812, a dielectric layer 814, an ESL 816, a dielectric layer 818, an ESL 820, a dielectric layer 822, an ESL 824, and a dielectric layer 826, among other examples. The dielectric layers 806, 810, 814, 818, 822, and 826 are included to electrically isolate various structures of the device 800. The dielectric layers 806, 810, 814, 818, 822, and 826 include a silicon nitride (SiNₓ), an oxide (e.g., a silicon oxide (SiOₓ) and/or another oxide material), and/or another type of dielectric material. The ESLs 808, 812, 816, 820, 824 includes a layer of material that is configured to permit various portions of the device 800 (or the layers included therein) to be selectively etched or protected from etching to form one or more of the structures included in the device 800.

As further shown in FIG. 8, the device 800 includes a plurality of epitaxial (epi) regions 828 that are grown and/or otherwise formed on and/or around portions of the fin structure 804. The epitaxial regions 828 are formed by epitaxial growth. In some implementations, the epitaxial regions 828 are formed in recessed portions in the fin structure 804. The recessed portions may be formed by strained source drain (SSD) etching of the fin structure 804 and/or another type etching operation. The epitaxial regions 828 function as source or drain regions of the transistors included in the device 800.

The epitaxial regions 828 are electrically connected to metal source or drain contacts 830 of the transistors included in the device 800. The metal source or drain contacts (MDs or CAs) 830 include cobalt (Co), ruthenium (Ru), and/or another conductive or metal material. The transistors further include gates 832 (MGs), which are formed of a polysilicon material, a metal (e.g., tungsten (W) or another metal), and/or another type of conductive material. The metal source or drain contacts 830 and the gates 832 are electrically isolated by one or more sidewall spacers, including spacers 834 on each side of the metal source or drain contacts 830 and spacers 836 on each side of the gate 832. The spacers 834 and 836 include a silicon oxide (SiOₓ), a silicon nitride (SiₓN_{y}), a silicon oxy carbide (SiOC), a silicon oxycarbonitride (SiOCN), and/or another suitable material. In some implementations, the spacers 834 are omitted from the sidewalls of the source or drain contacts 830.

As further shown in FIG. 8, the metal source or drain contacts 830 and the gates 832 are electrically connected to one or more types of interconnects. The interconnects electrically connect the transistors of the device 800 and/or electrically connect the transistors to other areas and/or components of the device 800. In some implementations, the interconnects electrically connect the transistors to a back end of line (BEOL) region of the device 800.

The metal source or drain contacts 830 are electrically connected to source or drain interconnects 838 (e.g., source/drain vias or VDs). One or more of the gates 832 are electrically connected to gate interconnects 840 (e.g., gate vias or VGs). The interconnects 838 and 840 include a conductive material such as tungsten, cobalt, ruthenium, copper, and/or another type of conductive material. In some implementations, the gates 832 are electrically connected to the gate interconnects 840 by gate contacts 842 (CB or MP) to reduce contact resistance between the gates 832 and the gate interconnects 840. The gate contacts 842 include tungsten (W), cobalt (Co), ruthenium (Ru), titanium (Ti), aluminum (Al), copper (Cu) or gold (Au), among other examples of conductive materials.

As further shown in FIG. 8, the interconnects 838 and 840 are electrically connected to a plurality of BEOL layers, each including one or more metallization layers and/or vias. As an example, the interconnects 838 and 840 may be electrically connected to an MO metallization layer that includes conductive structures 844 and 846. The MO metallization layer is electrically connected to a VO via layer that includes vias 848 and 850. The VO via layer is electrically connected to an Ml metallization that includes conductive structures 852 and 854. In some implementations, the BEOL layers of the device 800 includes additional metallization layers and/or vias that connect the device 800 to a package.

In some implementations, one or more of the example implementations of FTJ structures 202 described herein may be included in one or more layers or regions of the device 800. For example, an FTJ structure 202 may be included in the BEOL region of the device 800. Here, the FTJ structure 202 may be included in a dielectric layer (e.g., one of the dielectric layers 810, 814, 818, 822, or 826) and/or between vertically adjacent dielectric layers in the BEOL region. In some implementations, a combination of the interconnects 838, 840; a combination of the conductive structures 844, 846, 852, 854; and/or a combination of the vias 848, 850 may correspond to the bottom electrode 206 and the top electrode 208 of the FTJ structure 202. In some implementations, one or more of the example implementations of FeRAM cell (e.g., memory cell structure 302) described herein may be included in one or more layers or regions of the device 800.

As indicated above, FIG. 8 is provided as an example. Other examples may differ from what is described with regard to FIG. 8.

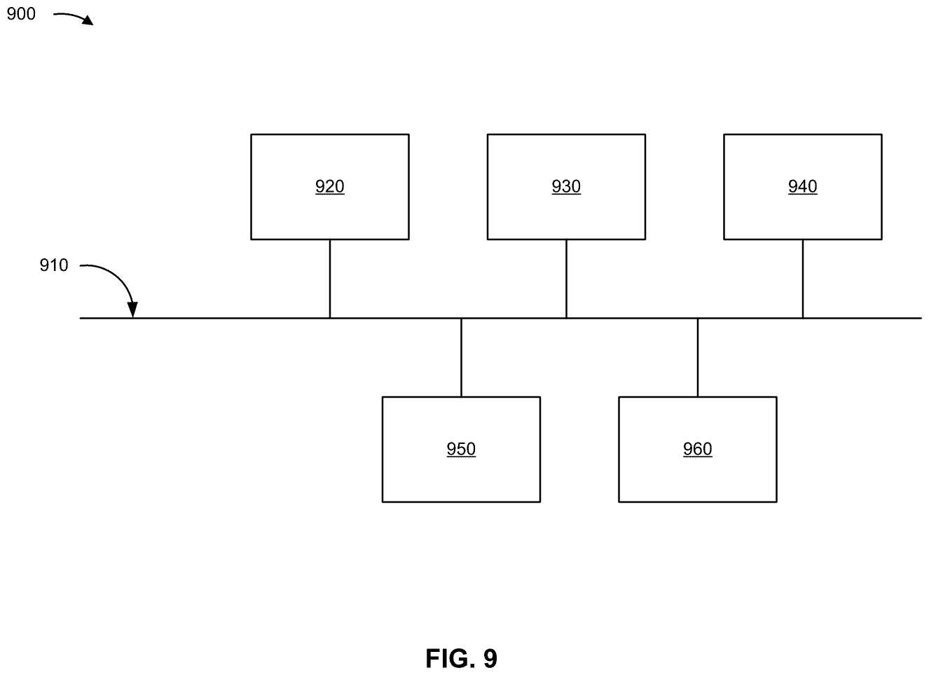

FIG. 9 is a diagram of example components of a device 900 described herein. In some implementations, one or more of the semiconductor processing tools 102-112 and/or the wafer/die transport tool 114 may include one or more devices 900 and/or one or more components of the device 900. As shown in FIG. 9, the device 900 may include a bus 910, a processor 920, a memory 930, an input component 940, an output component 950, and/or a communication component 960.

The bus 910 may include one or more components that enable wired and/or wireless communication among the components of the device 900. The bus 910 may couple together two or more components of FIG. 9, such as via operative coupling, communicative coupling, electronic coupling, and/or electric coupling. For example, the bus 910 may include an electrical connection (e.g., a wire, a trace, and/or a lead) and/or a wireless bus. The processor 920 may include a central processing unit, a graphics processing unit, a microprocessor, a controller, a microcontroller, a digital signal processor, a field-programmable gate array, an application-specific integrated circuit, and/or another type of processing component. The processor 920 may be implemented in hardware, firmware, or a combination of hardware and software. In some implementations, the processor 920 may include one or more processors capable of being programmed to perform one or more operations or processes described elsewhere herein.

The memory 930 may include volatile and/or nonvolatile memory. For example, the memory 930 may include random access memory (RAM), read only memory (ROM), a hard disk drive, and/or another type of memory (e.g., a flash memory, a magnetic memory, and/or an optical memory). The memory 930 may include internal memory (e.g., RAM, ROM, or a hard disk drive) and/or removable memory (e.g., removable via a universal serial bus connection). The memory 930 may be a non-transitory computer-readable medium. The memory 930 may store information, one or more instructions, and/or software (e.g., one or more software applications) related to the operation of the device 900. In some implementations, the memory 930 may include one or more memories that are coupled (e.g., communicatively coupled) to one or more processors (e.g., processor 920), such as via the bus 910. Communicative coupling between a processor 920 and a memory 930 may enable the processor 920 to read and/or process information stored in the memory 930 and/or to store information in the memory 930.

The input component 940 may enable the device 900 to receive input, such as user input and/or sensed input. For example, the input component 940 may include a touch screen, a keyboard, a keypad, a mouse, a button, a microphone, a switch, a sensor, a global positioning system sensor, an accelerometer, a gyroscope, and/or an actuator. The output component 950 may enable the device 900 to provide output, such as via a display, a speaker, and/or a light-emitting diode. The communication component 960 may enable the device 900 to communicate with other devices via a wired connection and/or a wireless connection. For example, the communication component 960 may include a receiver, a transmitter, a transceiver, a modem, a network interface card, and/or an antenna.

The device 900 may perform one or more operations or processes described herein. For example, a non-transitory computer-readable medium (e.g., memory 930) may store a set of instructions (e.g., one or more instructions or code) for execution by the processor 920. The processor 920 may execute the set of instructions to perform one or more operations or processes described herein. In some implementations, execution of the set of instructions, by one or more processors 920, causes the one or more processors 920 and/or the device 900 to perform one or more operations or processes described herein. In some implementations, hardwired circuitry may be used instead of or in combination with the instructions to perform one or more operations or processes described herein. Additionally, or alternatively, the processor 920 may be configured to perform one or more operations or processes described herein. Thus, implementations described herein are not limited to any specific combination of hardware circuitry and software.

The number and arrangement of components shown in FIG. 9 are provided as an example. The device 900 may include additional components, fewer components, different components, or differently arranged components than those shown in FIG. 9. Additionally, or alternatively, a set of components (e.g., one or more components) of the device 900 may perform one or more functions described as being performed by another set of components of the device 900.

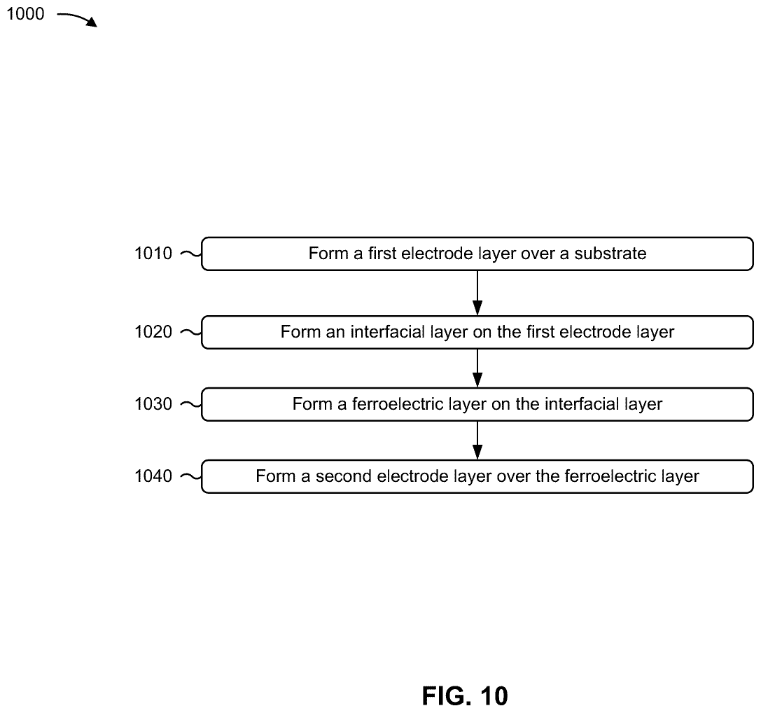

FIG. 10 is a flowchart of an example process 1000 associated with forming a semiconductor device described herein. In some implementations, one or more process blocks of FIG. 10 are performed by one or more semiconductor processing tools (e.g., one or more of the semiconductor processing tools 102-112). Additionally, or alternatively, one or more process blocks of FIG. 10 may be performed by one or more components of device 900, such as processor 920, memory 930, input component 940, output component 950, and/or communication component 960.

As shown in FIG. 10, process 1000 may include forming a first electrode layer over a substrate (block 1010). For example, one or more of the semiconductor processing tools 102-112 may form a first electrode layer (e.g., a bottom electrode 206) over a substrate 204, as described herein.

As further shown in FIG. 10, process 1000 may include forming an interfacial layer on the first electrode layer (block 1020). For example, one or more of the semiconductor processing tools 102-112 may form an interfacial layer 210 on the first electrode layer, as described herein. In some implementations, the interfacial layer 210 is formed such that the interfacial layer 210 has a centrosymmetric crystal structure.

As further shown in FIG. 10, process 1000 may include forming a ferroelectric layer on the interfacial layer (block 1030). For example, one or more of the semiconductor processing tools 102-112 may form a ferroelectric layer 212 on the interfacial layer 210, as described herein.

As further shown in FIG. 10, process 1000 may include forming a second electrode layer over the ferroelectric layer (block 1040). For example, one or more of the semiconductor processing tools 102-112 may form a second electrode layer (e.g., a top electrode 208) over the ferroelectric layer 212, as described herein.

Process 1000 may include additional implementations, such as any single implementation or any combination of implementations described below and/or in connection with one or more other processes described elsewhere herein.

In a first implementation, forming the ferroelectric layer 212 includes forming the ferroelectric layer 212 such that the ferroelectric layer 212 has a non-centrosymmetric crystal structure.

In a second implementation, alone or in combination with the first implementation, the centrosymmetric crystal structure promotes formation of an orthorhombic phase in the ferroelectric layer 212.

In a third implementation, alone or in combination with one or more of the first and second implementations, forming the interfacial layer 210 includes forming the interfacial layer 210 such that a grain size 704 of the interfacial layer 210 promotes formation of an orthorhombic phase in the ferroelectric layer 212.

In a fourth implementation, alone or in combination with one or more of the first through third implementations, forming the interfacial layer 210 includes forming the interfacial layer 210 such that a grain size of the interfacial layer 210 is included in a range of approximately 2 nanometers to approximately 10 nanometers.

In a fifth implementation, alone or in combination with one or more of the first through fourth implementations, forming the interfacial layer 210 includes forming the interfacial layer 210 to a thickness that is included in a range of approximately 0.5 nanometers to approximately 3 nanometers.

In a sixth implementation, alone or in combination with one or more of the first through fifth implementations, forming the interfacial layer 210 includes forming the interfacial layer 210 such that the interfacial layer 210 includes a material that has a dielectric constant that is included in a range of approximately 5 to approximately 50.

Although FIG. 10 shows example blocks of process 1000, in some implementations, process 1000 includes additional blocks, fewer blocks, different blocks, or differently arranged blocks than those depicted in FIG. 10. Additionally, or alternatively, two or more of the blocks of process 1000 may be performed in parallel.

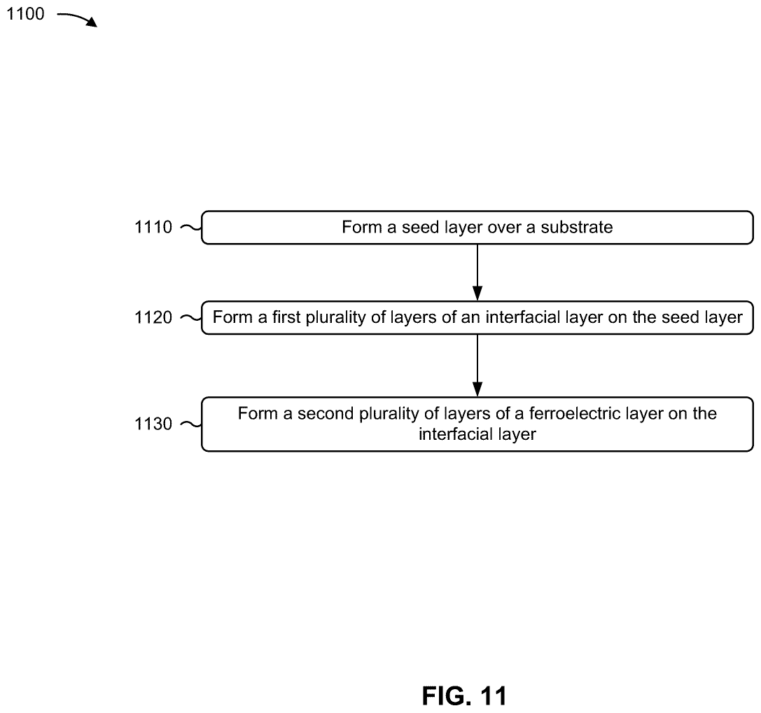

FIG. 11 is a flowchart of an example process 1100 associated with forming a semiconductor device described herein. In some implementations, one or more process blocks of FIG. 11 are performed by one or more semiconductor processing tools (e.g., one or more of the semiconductor processing tools 102-112). Additionally, or alternatively, one or more process blocks of FIG. 11 may be performed by one or more components of device 900, such as processor 920, memory 930, input component 940, output component 950, and/or communication component 960.

As shown in FIG. 11, process 1100 may include forming a seed layer over a substrate (block 1110). For example, one or more of the semiconductor processing tools 102-112 may form a seed layer 502 over a substrate 204, as described herein.

As further shown in FIG. 11, process 1100 may include forming a first plurality of layers of an interfacial layer on the seed layer (block 1120). For example, one or more of the semiconductor processing tools 102-112 may form a first plurality of layers (e.g., a layer 602, a layer 604) of an interfacial layer 210 on the seed layer 502, as described herein. In some implementations, the seed layer 502 promotes forming the interfacial layer 210 to a grain size in a particular grain size range.

As further shown in FIG. 11, process 1100 may include forming a second plurality of layers of a ferroelectric layer on the interfacial layer (block 1130). For example, one or more of the semiconductor processing tools 102-112 may form a second plurality of layers of a ferroelectric layer 212 on the interfacial layer 210, as described herein.

Process 1100 may include additional implementations, such as any single implementation or any combination of implementations described below and/or in connection with one or more other processes described elsewhere herein.

In a first implementation, forming the first plurality of layers of the interfacial layer 210 includes forming a first layer (e.g., a layer 602), of the first plurality of layers, on the seed layer 502, annealing the first layer after forming the first layer, forming a second layer (e.g., a layer 604), of the first plurality of layers, on the first layer, and annealing the second layer after forming the second layer.

In a second implementation, alone or in combination with the first implementation, annealing the first layer causes a crystal structure of the first layer to conform to a crystal structure of the seed layer 502, and annealing the second layer causes the crystal structure of the second layer to conform to the crystal structure of the first layer.

In a third implementation, alone or in combination with one or more of the first and second implementations, the first layer has an amorphous structure prior to annealing the first layer, and the annealing the first layer transforms the amorphous structure to a centrosymmetric crystal structure.

In a fourth implementation, alone or in combination with one or more of the first through third implementations, forming the first plurality of layers of the interfacial layer 210 includes forming the first plurality of layers of the interfacial layer 210 such that the interfacial layer 210 has a centrosymmetric crystal structure, where the centrosymmetric crystal structure promotes formation of a non-centrosymmetric crystal structure in the ferroelectric layer 212.

In a fifth implementation, alone or in combination with one or more of the first through fourth implementations, forming the interfacial layer 210 to the grain size in the particular grain size range promotes formation of the ferroelectric layer 212 such that the ferroelectric layer 212 has a grain size that is included in a range of approximately 2 nanometers to approximately 15 nanometers.

In a sixth implementation, alone or in combination with one or more of the first through fifth implementations, forming the interfacial layer 210 to the grain size in the particular grain size range promotes formation of the ferroelectric layer 212 such that the ferroelectric layer 212 has a grain size that promotes formation of an orthorhombic phase in the ferroelectric layer 212.

Although FIG. 11 shows example blocks of process 1100, in some implementations, process 1100 includes additional blocks, fewer blocks, different blocks, or differently arranged blocks than those depicted in FIG. 11. Additionally, or alternatively, two or more of the blocks of process 1100 may be performed in parallel.

In this way, an interfacial layer is formed in a manner that enables the ferroelectric layer to be formed to increase the formation of ferroelectric crystalline phases (e.g., orthorhombic crystalline phases) in the ferroelectric layer, and to reduce the formation of non-ferroelectric crystalline phases (e.g., monoclinic phases, tetragonal phases) in the ferroelectric layer. To achieve this, the grain size and/or other properties of the interfacial layer may be controlled during formation of the interfacial layer such that the grain size and/or other properties of the interfacial layer facilitate formation of a larger grain size in the ferroelectric layer. At larger grain sizes in the ferroelectric layer, the concentration of ferroelectric crystalline phases (e.g., orthorhombic crystalline phases) in the crystal structure of the ferroelectric layer may be increased relative to smaller grain sizes in the ferroelectric layer.

As described in greater detail above, some implementations described herein provide a method. The method includes forming a first electrode layer over a substrate. The method includes forming an interfacial layer on the first electrode layer, where the interfacial layer is formed such that the interfacial layer has a centrosymmetric crystal structure. The method includes forming a ferroelectric layer on the interfacial layer. The method includes forming a second electrode layer over the ferroelectric layer.

As described in greater detail above, some implementations described herein provide a method. The method includes forming a seed layer over a substrate. The method includes forming a first plurality of layers of an interfacial layer on the seed layer, where the seed layer promotes forming the interfacial layer to a grain size in a particular grain size range. The method includes forming a second plurality of layers of a ferroelectric layer on the interfacial layer.

As described in greater detail above, some implementations described herein provide a FTJ structure. The FTJ structure includes a bottom electrode. The FTJ structure includes a top electrode above the bottom electrode. The FTJ structure includes an interfacial layer between the bottom electrode and the top electrode, where the interfacial layer has a centrosymmetric crystal structure. The FTJ structure includes a ferroelectric layer between the bottom electrode and the top electrode, and vertically adjacent with the interfacial layer, where the ferroelectric layer has a non-centrosymmetric crystal structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a first electrode layer over a substrate;
forming an interfacial layer on the first electrode layer,
wherein the interfacial layer is formed such that the interfacial layer has a centrosymmetric crystal structure;
forming a ferroelectric layer on the interfacial layer; and
forming a second electrode layer over the ferroelectric layer.

2. The method of claim 1, wherein forming the ferroelectric layer comprises:
forming the ferroelectric layer such that the ferroelectric layer has a non-centrosymmetric crystal structure.

3. The method of claim 1, wherein the centrosymmetric crystal structure promotes formation of an orthorhombic phase in the ferroelectric layer.

4. The method of claim 1, wherein forming the interfacial layer comprises:
forming the interfacial layer such that a grain size of the interfacial layer promotes formation of an orthorhombic phase in the ferroelectric layer.

5. The method of claim 1, wherein forming the interfacial layer comprises:
forming the interfacial layer such that a grain size of the interfacial layer is included in a range of approximately 2 nanometers to approximately 10 nanometers.

6. The method of claim 1, wherein forming the interfacial layer comprises:
forming the interfacial layer to a thickness that is included in a range of approximately 0.5 nanometers to approximately 3 nanometers.

7. The method of claim 1, wherein forming the interfacial layer comprises:
forming the interfacial layer such that the interfacial layer includes a material that has a dielectric constant that is included in a range of approximately 5 to approximately 50.

8. A method, comprising:
forming a seed layer over a substrate;
forming a first plurality of layers of an interfacial layer on the seed layer,
wherein the seed layer promotes forming the interfacial layer to a grain size in a particular grain size range; and
forming a second plurality of layers of a ferroelectric layer on the interfacial layer.

9. The method of claim 8, wherein forming the first plurality of layers of the interfacial layer comprises:
forming a first layer, of the first plurality of layers, on the seed layer;
annealing the first layer after forming the first layer;
forming a second layer, of the first plurality of layers, on the first layer; and
annealing the second layer after forming the second layer.

10. The method of claim 9, wherein annealing the first layer causes a crystal structure of the first layer to conform to a crystal structure of the seed layer; and
wherein annealing the second layer causes a crystal structure of the second layer to conform to the crystal structure of the first layer.

11. The method of claim 9, wherein the first layer has an amorphous structure prior to annealing the first layer; and
wherein the annealing the first layer transforms the amorphous structure to a centrosymmetric crystal structure.

12. The method of claim 8, wherein forming the first plurality of layers of the interfacial layer comprises:
forming the first plurality of layers of the interfacial layer such that the interfacial layer has a centrosymmetric crystal structure,
wherein the centrosymmetric crystal structure promotes formation of a non-centrosymmetric crystal structure in the ferroelectric layer.

13. The method of claim 8, wherein forming the interfacial layer to the grain size in the particular grain size range promotes formation of the ferroelectric layer such that the ferroelectric layer has a grain size that is included in a range of approximately 2 nanometers to approximately 15 nanometers.

14. The method of claim 8, wherein forming the interfacial layer to the grain size in the particular grain size range promotes formation of the ferroelectric layer such that the ferroelectric layer has a grain size that promotes formation of an orthorhombic phase in the ferroelectric layer.

15. A ferroelectric tunnel junction (FTJ) structure, comprising:
a bottom electrode;
a top electrode above the bottom electrode;
an interfacial layer between the bottom electrode and the top electrode,
wherein the interfacial layer has a centrosymmetric crystal structure; and
a ferroelectric layer between the bottom electrode and the top electrode, and vertically adjacent with the interfacial layer,
wherein the ferroelectric layer has a non-centrosymmetric crystal structure.

16. The FTJ structure of claim 15, wherein the interfacial layer is below the ferroelectric layer.

17. The FTJ structure of claim 15, wherein the interfacial layer is above the ferroelectric layer.

18. The FTJ structure of claim 15, wherein the bottom electrode, the top electrode, the interfacial layer, and the ferroelectric layer are arranged in a deep trench configuration that extends below a top surface of a substrate.

19. The FTJ structure of claim 15, wherein the FTJ structure is included in a memory cell structure; and
wherein the FTJ structure is electrically connected with a source/drain region of a transistor of the memory cell structure.

20. The FTJ structure of claim 15, wherein the FTJ structure is included in a ferroelectric field effect transistor (FeFET) structure of a memory cell structure;
wherein the bottom electrode corresponds to a channel layer of the FeFET structure;
wherein the top electrode corresponds to a gate electrode of the FeFET structure;
wherein the interfacial layer corresponds to a gate dielectric layer of the FeFET structure; and
wherein the ferroelectric layer corresponds to a ferroelectric switching layer of the FeFET structure.
